(19) United States
(12) Patent Application Publication
(10) Pub. No.: US 2026/0282884 A1
(43) Pub. Date: Sep. 17, 2026

(54) SEMICONDUCTOR DEVICE AND METHOD OF MANUFACTURING THE SAME

(71) Applicant: Taiwan Semiconductor Manufacturing Company, Ltd., Hsinchu (TW)

(72) Inventors: Hung-Chang Sun, Kaohsiung City (TW); Chieh-Fang Chen, Hsinchu County (TW); Chen-Jun Wu, Hsinchu City (TW); Chung-Te Lin, Tainan City (TW); Katherine H. Chiang, New Taipei City (TW)

(21) Appl. No.: 19/275,032

(22) Filed: Jul. 21, 2025

Related U.S. Application Data
(60) Provisional application No. 63/773,041, filed on Mar. 17, 2025.

(51) Int. Cl. H01L 23/528; H01L 21/768; H01L 23/00; H01L 23/522; H01L 23/532; H01L 25/03; H01L 25/065; H10B 12/00

(52) U.S. Cl. CPC H10W 20/435; H10W 20/056; H10W 20/089; H10W 20/42; H10W 20/425; H10W 20/43; H10W 20/4446; H10W 20/496; H10W 20/498; H10B 12/0335; H10B 12/315; H10B 12/50; H10W 70/09; H10W 70/60; H10W 70/6528; H10W 90/00; H10W 90/10; H10W 90/724

(57) ABSTRACT

In some embodiments, a semiconductor structure including an interconnect structure disposed within a dielectric layer is provided. The interconnect structure includes a first lateral conductive portion extending in a first lateral direction and vertically between a lower conductive layer and an upper conductive layer, and a vertical conductive portion extending in a vertical direction, from the lower conductive layer to the upper conductive layer, and laterally contacting the first lateral conductive portion in the first lateral direction.

### REFERENCE TO RELATED APPLICATION

This Application claims the benefit of U.S. Provisional Application number 63/773,041, filed on Mar. 17, 2025, the contents of which are hereby incorporated by reference in their entirety.

### BACKGROUND

Modern-day integrated chips comprise millions or billions of semiconductor devices (such as integrated chip structures) formed on a semiconductor substrate (e.g., a silicon substrate). The semiconductor devices are electrically coupled together by interconnects. The interconnects comprise interconnect wires and interconnect vias disposed within a dielectric structure over a semiconductor substrate. By using interconnects to electrically couple the semiconductor devices together, the semiconductor devices are able to perform logical functions that enable operation of an integrated chip.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a cross-sectional view of some embodiments of an integrated chip structure having a deep via extending over multiple interconnect layers.

FIG. 1B illustrates a top view of some embodiments of a portion of the integrated chip structure taken along line A-A′ in FIG. 1A.

FIGS. 1C-1F illustrate cross-sectional views of various embodiments of a portion of the integrated chip structure in FIG. 1A.

FIG. 2A illustrates a cross-sectional view of some additional embodiments of an integrated chip structure having a deep via extending over multiple interconnect layers.

FIG. 2B illustrates a top view of some embodiments of a portion of the integrated chip structure taken along line B-B′ in FIG. 2A.

FIG. 3A illustrates a cross-sectional view of some additional embodiments of an integrated chip structure having a deep via extending over multiple interconnect layers.

FIG. 3B illustrates a top view of some embodiments of a portion of the integrated chip structure taken along line C-C′ in FIG. 3A.

FIGS. 4-17 are a series of cross-sectional views of intermediate semiconductor structures that illustrate some exemplary steps of a method for manufacturing an integrated chip structure having a deep via extending over multiple interconnect layers in FIG. 2A.

FIG. 12A illustrates a top view of some embodiments of a portion of the integrated chip structure in FIG. 12.

FIG. 13A illustrates a top view of some embodiments of a portion of the integrated chip structure in FIG. 13.

FIG. 16A illustrates a top view of some embodiments of a portion of the integrated chip structure in FIG. 16.

FIG. 18 illustrates a flow diagram of some embodiments of a method for manufacturing an integrated chip structure having a deep via extending over multiple interconnect layers in FIG. 2A.

FIGS. 19-34 are a series of cross-sectional views of intermediate semiconductor structures that illustrate some exemplary steps of a method for manufacturing an integrated chip structure having a deep via extending over multiple interconnect layers in FIG. 3A.

FIG. 35 illustrates a flow diagram of some embodiments of a method for manufacturing an integrated chip structure having a deep via extending over multiple interconnect layers in FIG. 3A.

FIG. 36 illustrates a cross-sectional view of some additional embodiments of an integrated chip structure having a deep via extending over multiple interconnect layers.

FIG. 37 illustrates a cross-sectional view of some additional embodiments of an integrated chip structure having a deep via extending over multiple interconnect layers.

FIG. 38 illustrates a cross-sectional view of some additional embodiments of an integrated chip structure having a deep via extending over multiple interconnect layers.

FIG. 39 illustrates a cross-sectional view of some additional embodiments of an integrated chip structure having a deep via extending over multiple interconnect layers.

FIG. 40A illustrates a cross-sectional view of some additional embodiments of an integrated chip structure having deep via extending over multiple interconnect layers.

FIG. 40B illustrates a 3D view of the integrated chip structure of FIG. 40A.

FIGS. 41-50 illustrate cross-sectional views of some additional embodiments to a method of forming an integrated chip structure in FIG. 39 having a deep via extending over multiple interconnect layers.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In some embodiments, the terms “approximately” and/or “about” can be interpreted as meaning +/−10% or +/−5%, while in other embodiments, the terms “approximately” and/or “about” can be interpreted as meaning within the normal fabrication tolerances of a given fab manufacturing flow.

Integrated chip structures include conductive interconnects disposed over a substrate. The conductive interconnects comprise alternating layers of conductive wires and conductive vias that increase in size as a distance over the substrate increases. The conductive wires are configured to provide for lateral routing, while the conductive vias are configured to provide for vertical routing between adjacent conductive wires. For example, a first conductive via may provide for vertical routing between an underlying conductive wire and an overlying conductive wire. The conductive interconnects are often formed using one or more damascene processes (e.g., a single damascene process or a dual damascene process). The damascene process is performed, for example, by forming an ILD layer over the substrate, etching the ILD layer to form a hole and/or a trench, and filling the hole and/or trench with a conductive material.

The use of damascene processes to form conductive interconnects may require different masks for each of the interconnect wire and via layers. Furthermore, in a single damascene process, multiple planarization processes (e.g., CMP processes) may be used during the formation of each of the interconnect wire and via layers. The lithography and CMP processes used to form interconnect layers are expensive and time consuming. For example, Back-end-of-line (BEOL) interconnect stacks with many interconnect layers may use a large number of masks and/or CMP processes, thereby limiting throughput (e.g., limiting wafers per hour) and leading to high integrated chip production costs. Additionally, the control of overlay across multiple interconnect wire and via layers is also a challenge.

The present disclosure relates to a method of manufacturing an interconnect structure including at least a first conductive layer (or a first interconnect layer) and a second conductive layer (or a first interconnect layer) extending in a first lateral direction, and a deep conductive via extending in a vertical direction through the first conductive layer and the second conductive layer. In some embodiments, the method includes forming a first dielectric layer over a semiconductor substrate, forming a first sacrificial layer in the first dielectric layer, forming a second dielectric layer over the first dielectric layer and the first sacrificial layer, forming a second sacrificial layer in the second dielectric layer, forming a deep opening vertically through the second sacrificial layer, the second dielectric layer, the first sacrificial layer, and the first dielectric layer, performing a removal process to laterally widen the deep opening, and remove the first and the second sacrificial layers laterally exposed by the deep opening to respectively form a first lateral opening and a second lateral opening, and filling the deep opening and the first lateral opening and the second lateral opening with a conductive filling material to respectively form the deep conductive via, the first conductive layer, and the second conductive layer, which combinedly form the interconnect structure. By forming the deep via to extend through at least the first conductive layer and the second conductive layer, the fabrication of the interconnect structure is simplified, thereby advantageously reducing production costs (e.g., by using less lithography and CMP processes), increasing a throughput of integrated chip structure fabrication, and improving controlling overlaying across multiple interconnect wire and interconnect via layers.

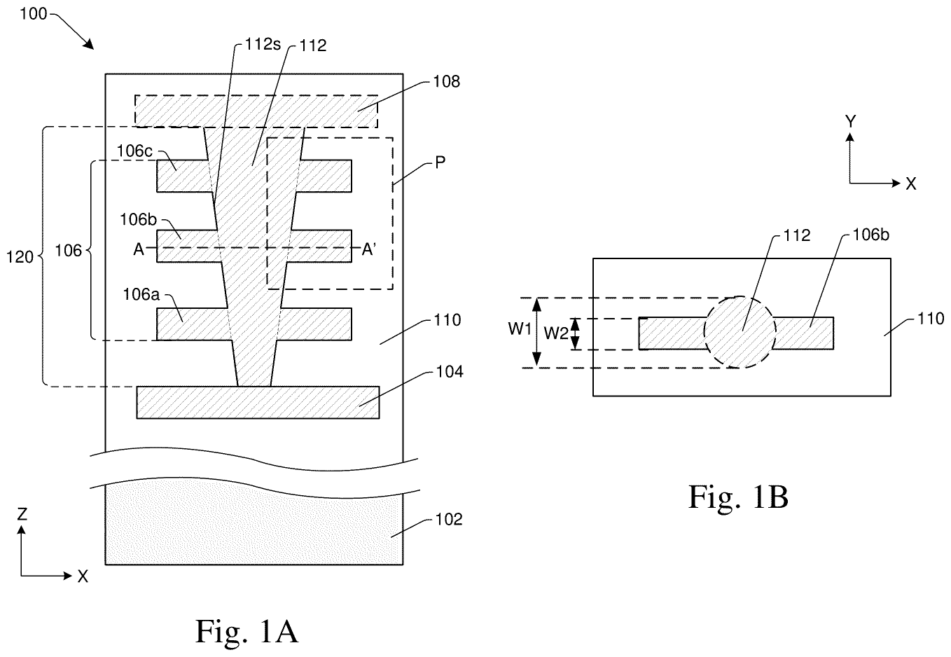

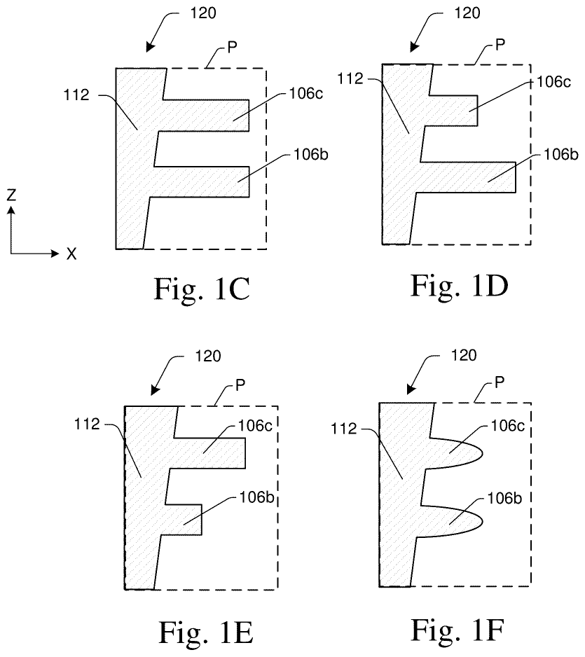

FIG. 1A illustrates a cross-sectional view of some embodiments of an integrated chip structure 100 having a deep conductive via 112 extending through one or more interconnect layers (or conductive layers) 106. In some embodiments, the integrated chip structure 100 includes a dielectric layer 110 disposed over a semiconductor substrate 102, and an interconnect structure 120 disposed within the dielectric layer 110. In some embodiments, the interconnect structure 120 includes one or more conductive layers 106 (e.g., 106a, 106b, and 106c) extending in a first lateral direction (e.g., X direction) and disposed vertically between a lower conductive layer 104 and an upper conductive layer 108, and a deep conductive via 112 extending through the one or more conductive layers 106 in a vertical direction (e.g., Z direction) and in contact with the one or more conductive layers 106. In some embodiments, the deep conductive via 112 is in connection with the lower conductive layer 104 and/or the upper conductive layer 108. Although the interconnect structure 120 illustrated in FIG. 1A includes three conductive layers 106 (e.g., 106a-106c), the interconnect structure 120 can include any number n of the conductive layers 106 without going beyond the scope of the present disclosure. In some embodiments, the number n of the conductive layers 106 in the interconnect structure 120 can be in a range from 1 to 20.

In some embodiments, the interconnect structure 120, including the conductive layers 106 and the deep conductive via 112, is made from or filled with a conductive filling material. In some embodiments, the conductive filling material may be TiN, W, Ru, TaN, Cu, or a combination thereof, or may be one of other metal materials. In some embodiments, a sidewall 112s of the deep conductive via 112 interfaces the dielectric layer 110, substantially extends from a top portion to a bottom portion thereof in or tilts a bit from the vertical direction (e.g., Z direction), and is advantageously smooth and continuous without any substantial curvature, protrusion, depression, or turning point.

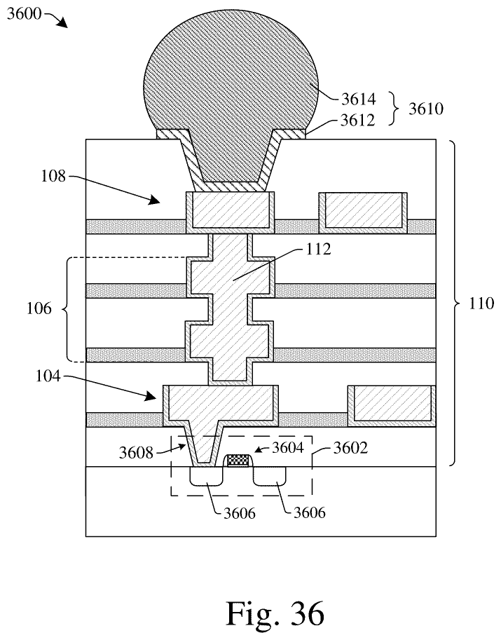

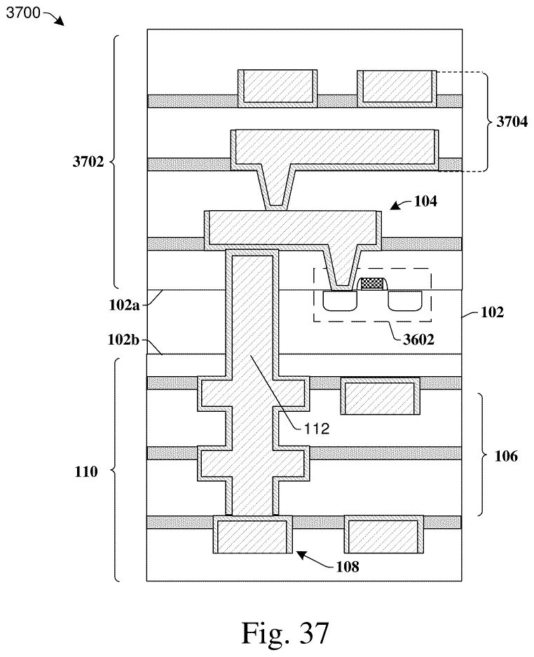

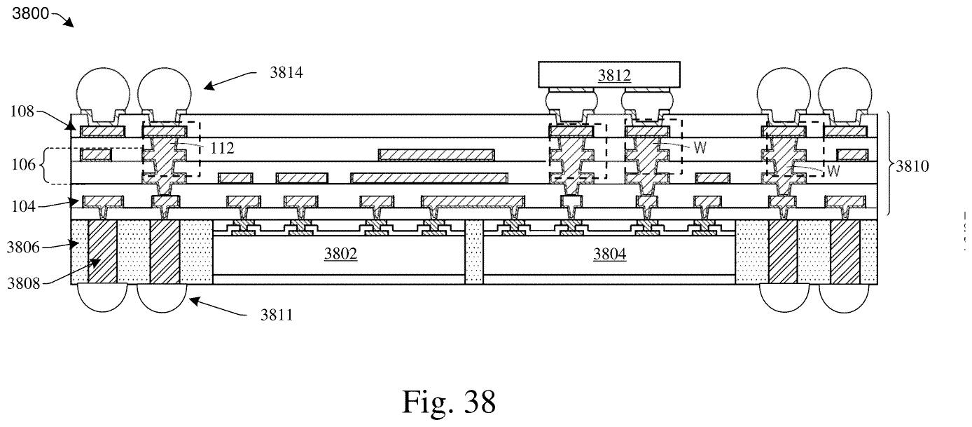

In some embodiments, the interconnect structure 120 is disposed over a semiconductor substrate 102 of a semiconductor die (e.g., in FIG. 1A and FIG. 36). In some embodiments, the interconnect structure 120 is disposed in a backside of a semiconductor die (e.g., in FIG. 37). In some embodiments, the interconnect structure 120 is disposed in a redistribution layer (RDL) of a semiconductor die (e.g., in FIG. 38).

FIG. 1B illustrates a top view of some embodiments of a portion P of the integrated chip structure 100 taken along line A-A′ in FIG. 1A. In some embodiments, a profile of the deep conductive via 112 is round-shaped from a top view as shown (e.g., in FIG. 1B), and in other embodiments, a profile of the deep conductive via 112 is slit-shaped from a top view (not shown). In some embodiments, the deep conductive via 112 is in contact with each (e.g., 106b) of the conductive layers 106. For example, a width W1 of the deep conductive via 112 in a second lateral direction (Y direction) perpendicular to the first lateral direction (X direction) at a level of the conductive layer 106b is greater than a width W2 of the conductive layer 106b. There is no need to reserve enclosure for the deep conductive via 112 landing on the conductive layers 106, thereby advantageously leading to improved self-alignment to enlarge process window. Thus, the odds for the integrated chip structure 100 experiencing open or short issues are greatly reduced or even eliminated, even if the deep conductive via 112 has an overlap shift relative to the conductive layers 106.

FIG. 1C illustrates a cross-sectional view of some embodiments of a portion P of the interconnect structure 120 of the integrated chip structure 100 in FIG. 1A. In some embodiments, sidewalls of the conductive layers 106 (e.g., 106b and 106c) have rectangular-shaped profiles and are co-planar along the vertical direction (e.g., Z direction) from the cross-sectional view in FIG. 1C. For example, the conductive layer 106b does not protrude or recess from the conductive layers 106c along the first lateral direction (X direction) in FIG. 1D, and vice versa.

FIG. 1D illustrates a cross-sectional view of some embodiments of a portion P of the interconnect structure 120 of the integrated chip structure 100. In some embodiments, sidewalls of the conductive layers 106 (e.g., 106b and 106c) have rectangular-shaped profiles and are not co-planar along the vertical direction (e.g., Z direction) from the cross-sectional view in FIG. 1D. For example, the conductive layers 106b protrudes from the conductive layers 106c along the first lateral direction (X direction) in FIG. 1D.

FIG. 1E illustrates a cross-sectional view of some embodiments of a portion P of the interconnect structure 120 of the integrated chip structure 100. In some embodiments, similarly, sidewalls of the conductive layers 106 (e.g., 106b and 106c) have rectangular-shaped profiles and are not co-planar along the vertical direction (Z direction) from the cross-sectional view in FIG. 1E. For example, the conductive layer 106c protrudes from the conductive layer 106b along the first lateral direction (X direction) in FIG. 1E.

FIG. 1F illustrates a cross-sectional view of some embodiments of a portion P of the interconnect structure 120 of the integrated chip structure 100. In some embodiments, sidewalls of the conductive layers 106 (e.g., 106b and 106c) have rounded profiles from the cross-sectional view in FIG. 1F.

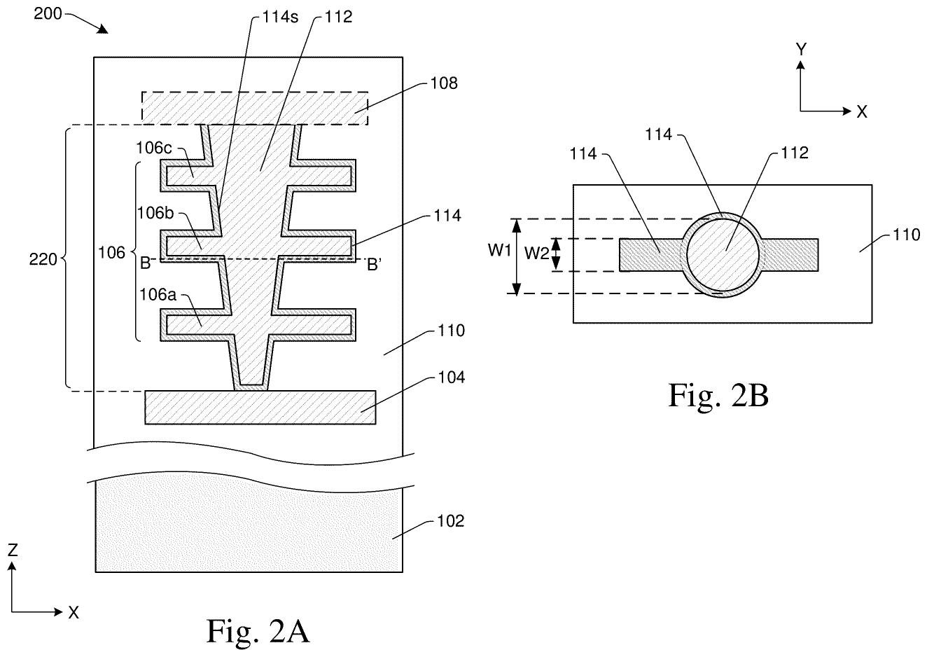

FIG. 2A illustrates a cross-sectional view of some additional embodiments of an integrated chip structure 200 having a deep conductive via 112 extending through one or more interconnect layers (or one or more conductive layers) 106. Similar to the embodiments as shown in FIG. 1A, the integrated chip structure 200 includes a dielectric layer 110 disposed over a semiconductor substrate 102, and an interconnect structure 220 disposed within the dielectric layer 110. In some embodiments, the interconnect structure 220 includes one or more conductive layers 106 (e.g., 106a, 106b, and 106c) extending in a first lateral direction (X direction) and disposed vertically between a lower conductive layer 104 and an upper conductive layer 108, and a deep conductive via 112 extending through the one or more conductive layers 106 in a vertical direction (e.g., Z direction) and in contact with the one or more conductive layers 106. In some embodiments, the deep conductive via 112 is in connection with the lower conductive layer 104 and/or the upper conductive layer 108. The interconnect structure 220 can include any number n of the conductive layers 106 without going beyond the scope of the present disclosure. For example, the number n of the conductive layers 106 in the interconnect structure 220 can be in a range from 1 to 20.

Similarly, the interconnect structure 220, including the conductive layers 106 and the deep conductive via 112, is made from or filled with a conductive filling material selected from TiN, W, Ru, TaN, Cu, or a combination thereof. In some embodiments, differently, the interconnect structure 220 further includes a conforming conductive liner 114 disposed between the conductive filling material and the surrounding dielectric layer 110, to separate them from each other. In some embodiments, the conforming conductive liner 114 includes a seed material that is TiN or TaN, and different from the filling conductive material. An inner surface 114s of the conductive liner 114, which interfaces the deep conductive via 112, substantially extends in the vertical direction (Z direction), and is advantageously smooth and continuous without any substantial curvature, protrusion, depression, or turning point.

FIG. 2B illustrates a top view of some embodiments of a portion of the integrated chip structure 200 taken along line B-B′ in FIG. 2A. In some embodiments, a profile of the deep conductive via 112 is round-shaped from a top view as shown (e.g., in FIG. 2B), and in other embodiments, a profile of the deep conductive via 112 is slit-shaped from a top view (not shown). For example, a width W1 of the deep conductive via 112 in a second lateral direction (Y direction) perpendicular to the first lateral direction (X direction) at a level of the conductive layer 106b is greater than a width W2 of the conductive layer 106b. In some embodiments, the conforming conductive liner 114 disposed on a sidewall of the interconnect structure 220 advantageously separates the conductive filling material filled thereof from the surrounding dielectric layer 110. For example, the conforming conductive liner 114 disposed on the sidewall of the deep conductive via 112 advantageously separates the conductive filling material filled therein from the dielectric layer 110.

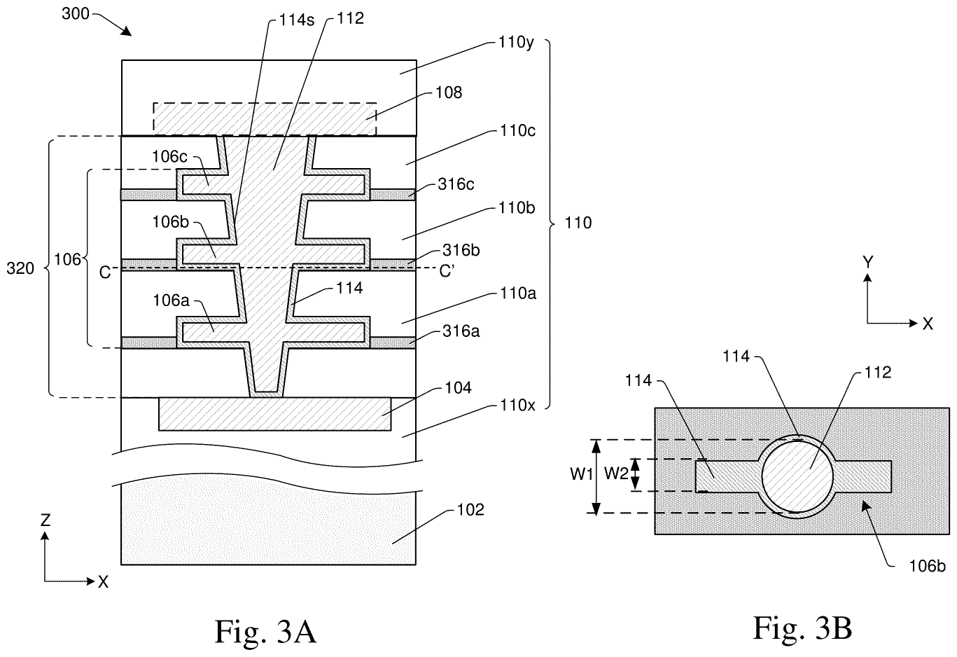

FIG. 3A illustrates a cross-sectional view of some additional embodiments of an integrated chip structure 300 having a deep conductive via 112 extending through one or more interconnect layers (or conductive layers) 106. In some embodiments, the integrated chip structure 300 includes an interlayer dielectric (ILD) structure 110 disposed over a semiconductor substrate 102, and an interconnect structure 320 disposed within the ILD structure 110.

In some embodiments, the ILD structure 110 includes multiple ILD layers (e.g., 110x, 110a-110c, and 110y) stacked onto one another. For example, a lower ILD 110x is disposed over a semiconductor substrate 102, one or more intermediate ILDs 110a-110c are disposed over the lower ILD 110x, and an upper ILD 110y is disposed over the intermediate ILDs 110a-110c as shown in FIG. 3A. In some embodiments, some of the multiple ILDs (e.g., 110x, 110a, 110b, and 110c) are vertically separated from one another by multiple etch stop layers (ESLs) (e.g., 316a-316c). The multiple ESLs may include a lower ESL 316a, one or more intermediates ESLs (e.g., 316b) over the lower ESL 316a, and an upper ESL 316c over the intermediates ESLs (e.g., 316b). The interconnect structure 320 can include any number n of the conductive layers 106 without going beyond the scope of the present disclosure. For example, the number n of the conductive layers 106 in the interconnect structure 320 can be in a range from 1 to 20.

In some embodiments, the interconnect structure 320 includes one or more conductive layers 106 (e.g., 106a, 106b, and 106c) extending in a first lateral direction (X direction) and disposed vertically between a lower conductive layer 104 and an upper conductive layer 108, and a deep conductive via 112 extending through some or all of the conductive layers 106 in a vertical direction (Z direction) and in contact with all of the conductive layers 106. In some embodiments, the deep conductive via 112 is in connection with the lower conductive layer 104 and/or the upper conductive layer 108. In some embodiments, a conductive layer 106a is disposed in a lower portion of the intermediate ILD layer 110a and downwardly extends through the ESL 316a, a conductive layer 106b is disposed in a lower portion of the intermediate ILD layer 110b and downwardly extends through the ESL 316b, and a conductive layer 106c is disposed in a lower portion of the intermediate ILD layer 110c and downwardly extends through the ESL 316c.

In some embodiments, similar to the implement in FIG. 2A, the interconnect structure 320 in FIG. 3A, including the conductive layers 106 and the deep conductive via 112, is made from or filled with a conductive filling material selected from TiN, W, Ru, TaN, Cu, or a combination thereof. In some embodiments, similar to the implement in FIG. 2A, the interconnect structure 320 further includes a conforming conductive liner 114 disposed between the conductive filling material filled in the interconnect structure 320 and the surrounding ILDs 110 (e.g., 110x, 110a, 110b, 110c), to isolate them from each other. In some embodiments, the conforming conductive liner 114 includes a seed material that is TiN or TaN, and different from the filling conductive material. An inner surface 114s of the conductive liner 114 interfacing the deep conductive via 112 substantially extends in the vertical direction (Z direction), and is advantageously smooth and continuous without any substantial curvature, protrusion, depression, or turning point.

In some embodiments, the interconnect structure 120, including the conductive layers 106 and the deep conductive via 112, is made from or filled with a conductive filling material. In some embodiments, the conductive filling material may be TiN, W, Ru, TaN, Cu, or a combination thereof, or may be one of other metal materials. In some embodiments, a sidewall 112s of the deep conductive via 112 interfaces the dielectric layer 110, substantially extends from a top portion to a bottom portion thereof in or tilts a bit from the vertical direction (e.g., Z direction), and is substantially smooth and continuous without any substantial curvature, protrusion, depression, or turning point.

FIG. 3B illustrates a top view of some embodiments of a portion of the integrated chip structure taken along line C-C′ in FIG. 3A. In some embodiments, a profile of the deep conductive via 112 is round-shaped from a top view as shown (e.g., in FIG. 3B), and in other embodiments, a profile of the deep conductive via 112 is slit-shaped from a top view (not shown). Similarly, a width W1 of the deep conductive via 112 in a second lateral direction (Y direction) perpendicular to the first lateral direction (X direction) at a level of the conductive layer 106b is greater than a width W2 of the conductive layer 106b. In some embodiments, the conforming conductive liner 114 disposed on a sidewall of the interconnect structure 320 advantageously separates the conductive filling material filled therein from the surrounding ILDs 110 (such as 110x and 110a-110c). For example, the conforming conductive liner 114 disposed on the sidewall of the deep conductive via 112 advantageously separates the conductive filling material filled therein from the surrounding ILDs 110.

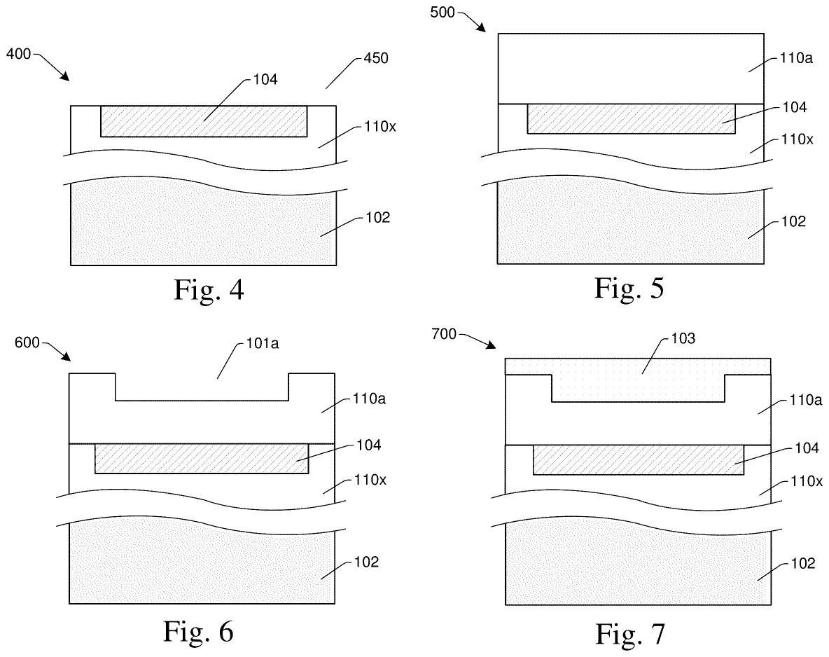

FIGS. 4-17 are a series of cross-sectional views of intermediate semiconductor structures that illustrate some exemplary steps of a method for manufacturing an integrated chip structure having a deep via extending through multiple interconnect layers in FIG. 2A. Although FIGS. 4-17 are described in relation to a method, it will be appreciated that the semiconductor structures disclosed in FIGS. 4-17 are not limited to such a method, but instead may stand alone as structures independent of the method.

As shown in cross-sectional view 400 of FIG. 4, a semiconductor structure 450 including a lower dielectric layer 110x over a substrate 102 is provided. In some embodiments, a lower conductive layer 104 is disposed in the lower dielectric layer 110x. In some embodiments, the substrate 102 may be any type of substrate (e.g., silicon, SiGe, SOI, etc.), such as a semiconductor wafer, as well as any other type of semiconductor and/or epitaxial layers, associated therewith. In some embodiments, a top surface of the lower conductive layer 104 is co-planar with a top surface of the lower dielectric layer 110x, and is exposed from the top surface of the lower dielectric layer 110x.

As shown in cross-sectional view 500 of FIG. 5, a first dielectric layer 110a is formed overlaying the top surfaces of the lower conductive layer 104 and the lower dielectric layer 110x by employing for example a deposition process (such as Chemical Vapor Deposition (CVD), Physical Vapor Deposition (PVD), and the like). In some embodiments, the first dielectric layer 110a may include a material such as silicon dioxide, carbon doped silicon oxide (SiCOH), phosphosilicate glass (PSG), borophosphosilicate glass (BPSG), borosilicate glass (BSG), fluorosilicate glass (FSG), undoped silicate glass (USG), and/or the like.

As shown in cross-sectional view 600 of FIG. 6, a first recess 101a is formed in an upper portion of the first dielectric layer 110a by employing for example an etching process (such as a dry etching process or a wet etching process).

As shown in cross-sectional view 700 of FIG. 7, the first recess 101a is filled with a sacrificial material 103 by employing for example a deposition process (such as CVD, PVD, and the like). In some embodiments, the sacrificial material 103 can be poly-Si, a-Si, SiN, Ge, SiGe, AlOx, or oxide, and the like, and the sacrificial material 103 is different from the material of the first dielectric layer 110a.

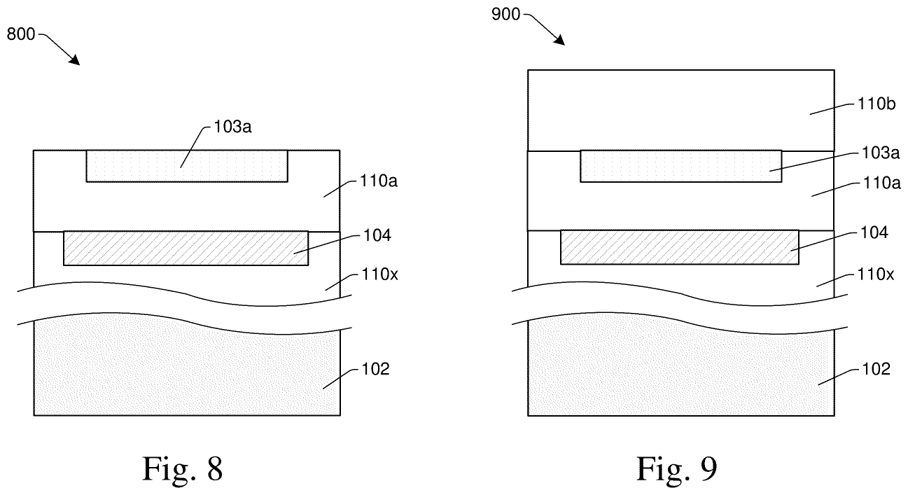

As shown in cross-sectional view 800 of FIG. 8, the sacrificial material 103 (in FIG. 7) outside the first recess 101a (in FIG. 6) is removed by employing for example a Chemical Mechanical Polishing (CMP) process. Thus, the top surfaces of the sacrificial material 103 and the first dielectric layer 110a are planarized by the CMP process, and thus are co-planar. Accordingly, a first sacrificial layer 103a is formed within an upper portion of the first dielectric layer 110a.

As shown in cross-sectional view 900 of FIG. 9, a second dielectric layer 110b is formed overlaying the top surfaces of the first sacrificial layer 103a and the first dielectric layer 110a by employing for example a deposition process (such as CVD, PVD, and the like). In some embodiments, the second dielectric layer 110b may include a same material as the first dielectric layer 110a, and in other embodiments, the second dielectric layer 110b may include a material different from that of the first dielectric layer 110a.

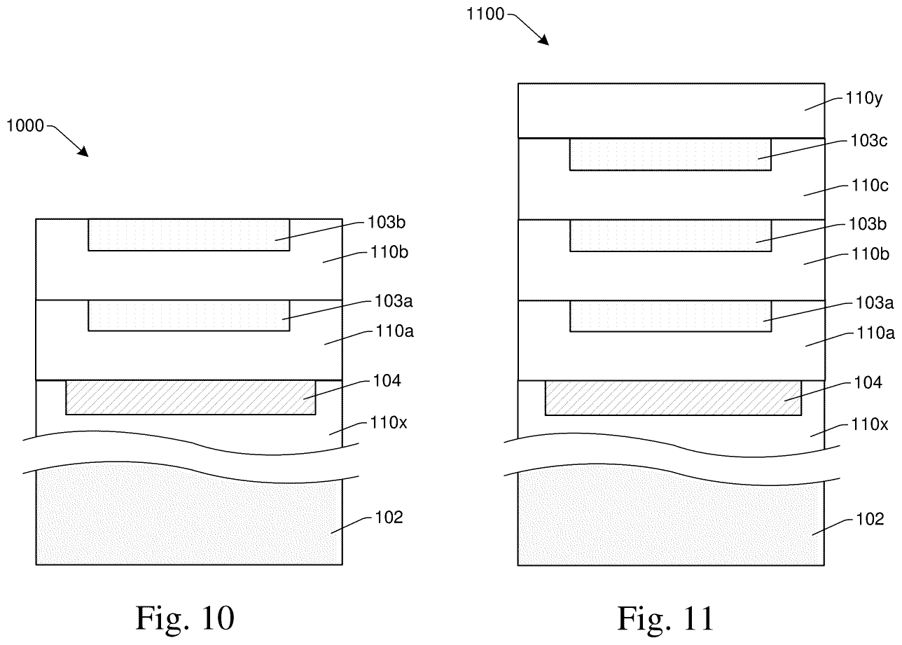

As shown in cross-sectional view 1000 of FIG. 10, a second sacrificial layer 103b is formed within an upper portion of the second dielectric layer 110b by employing processes similar to those as illustrated in FIGS. 5-8. In some embodiments, the second sacrificial layer (SL) 103b has a sacrificial material the same as that of the first sacrificial layer 103a, and in other embodiments, the second sacrificial layer 103b has a sacrificial material different from that of the first sacrificial layer 103a.

As shown in cross-sectional view 1100 of FIG. 11, a third dielectric layer 110c is formed over the top surfaces of the second sacrificial layer 103b and the second dielectric layer 110b, and then a third sacrificial layer 103c is formed within an upper portion of the third dielectric layer 110c, by employing processes similar to those as shown in FIGS. 5-8. In some embodiments, the third sacrificial layer 103c has a sacrificial material the same as that of the second sacrificial layer 103b, and in other embodiments, the third sacrificial layer 103c has a sacrificial material different from that of the second sacrificial layer 103b. Although three sacrificial layers (e.g., 103a, 103b, and 103c) are illustrated in the semiconductor structure as shown in FIG. 11, the number of sacrificial layers is not limited to three in the present disclosure. Any number (such as 1 to 15) of sacrificial layer(s) can be implemented in the present disclosure. In some embodiments, an upper dielectric layer 110y is additionally formed overlaying the top surfaces of the third sacrificial layer 103c and the third dielectric layer 110c.

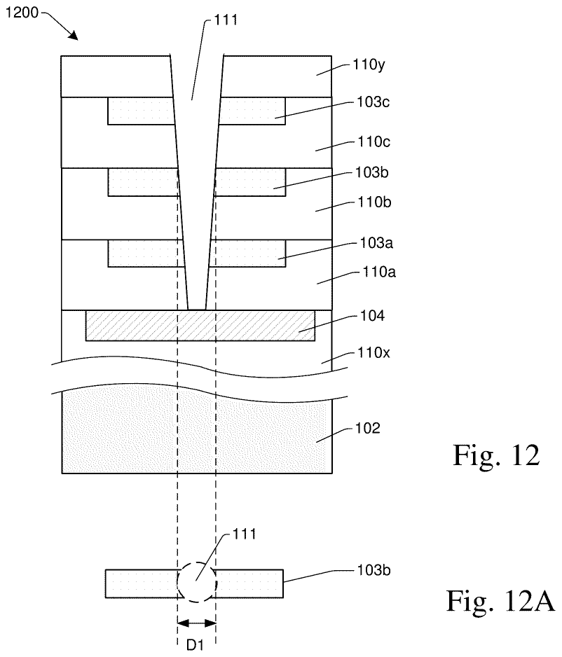

As shown in cross-sectional view 1200 of FIG. 12, a deep opening 111 is formed vertically through e.g., the upper dielectric layer 110y, the third sacrificial layer 103c, the third dielectric layer 110c, the second sacrificial layer 103b, the second dielectric layer 110b, the first sacrificial layer 103a, and the first dielectric layer 110a, by employing for example a lithography process followed by an anisotropic etching process (such as a dry etching process). In some embodiments, the deep opening 111 stops at the lower conductive layer 104, and exposes the lower conductive layer 104. Referring to FIG. 12A illustrating a top view of some embodiments of a portion of the integrated chip structure in FIG. 12, a profile of the deep opening 111 is round-shaped from the top view, and the deep via opening 111 has a diameter D1 at a level of the second sacrificial layer 103b.

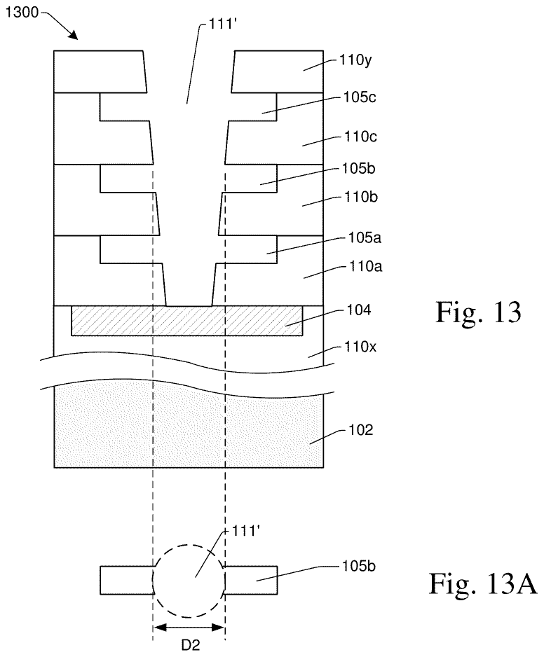

As shown in cross-sectional view 1300 of FIG. 13, a removal process is performed to laterally widen the deep opening 111 to form a widened deep opening 111', and to laterally remove all of the sacrificial layers (such as the first sacrificial layer 103a, the second sacrificial layer 103b, and the third sacrificial layer 103c) exposed by the deep opening 111 to respectively form lateral openings (such as a first lateral opening 105a, a second lateral opening 105b, and a third lateral opening 105c), by employing for example an isotropic etching process (such as a wet etching process). Referring to FIG. 13A illustrating a top view of some embodiments of a portion of the integrated chip structure in FIG. 13, a profile of the widened deep opening 111′ is round-shaped from the top view, and the widened deep opening 111′ has a widened diameter D2 greater than D1 at the level of the second lateral opening 105b.

In some embodiments, the material of the dielectric layers (such as 110a, 110b, and 110c) can be silicon dioxide, carbon doped silicon oxide (SiCOH), phosphosilicate glass (PSG), borophosphosilicate glass (BPSG), borosilicate glass (BSG), fluorosilicate glass (FSG), undoped silicate glass (USG), and/or the like; the material of the sacrificial layers (such as 103a, 103b, and 103c) can be poly-Si, a-Si, SiN, Ge, SiGe, AlOx, or oxide different from the material of the dielectric layers; and a wet solvent such as HF, dilute HF, H3PO4, or the like can be used to laterally widen the deep opening 111 to form the widened deep opening 111′ and to laterally remove all of the sacrificial layers (such as 103a, 103b and 103c) to form lateral openings (such as 105a, 105b, and 105c).

As such, the lateral openings (such as 105a, 105b, and 105c) and the widened deep opening 111′ are formed open to each other, and thus a spatially-connected chamber including the lateral openings and the widened deep via opening is created.

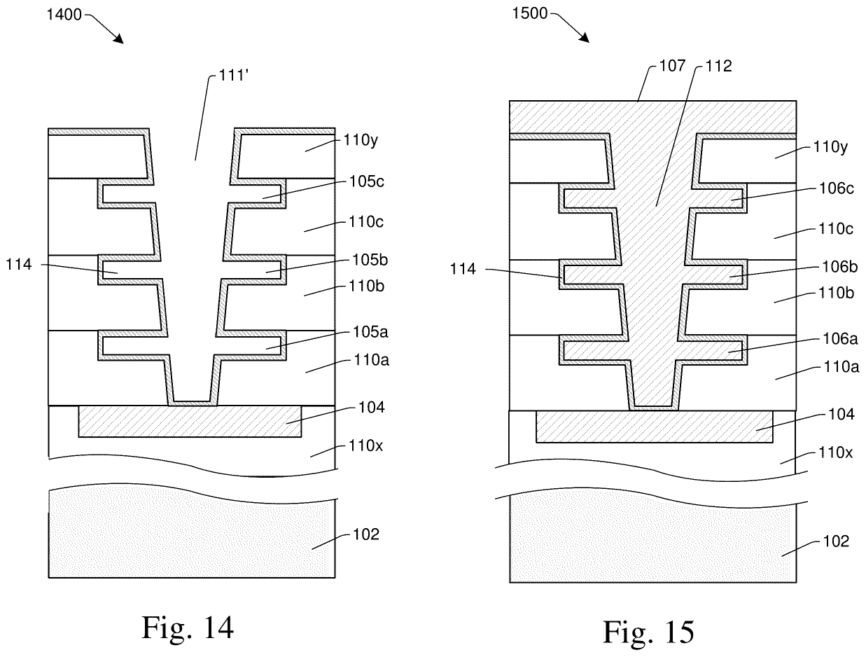

As shown in cross-sectional view 1400 of FIG. 14, a conductive liner 114 is formed on inner surfaces of the widened deep opening 111′ and the lateral openings (such as 105a, 105b, and 105c) of the spatially-connected chamber by employing for example a deposition process (such as a Plasma-Enhanced Atomic Layer Deposition (PEALD) process or a thermal Atomic Layer Deposition (ALD) process). In some embodiments, the conductive liner 114 includes a seed material that is for example TiN or TaN.

As shown in cross-sectional view 1500 of FIG. 15, a conductive filling material 107 (such as W or Cu) is filled into the spatially-connected chamber that includes the lateral openings (such as 105a, 105b, and 105c) and the widened deep opening 111′ by employing for example a deposition process (such as CVD, PVD, and the like) to respectively form conductive layers (such as 106a-106c) and a deep conductive via 112.

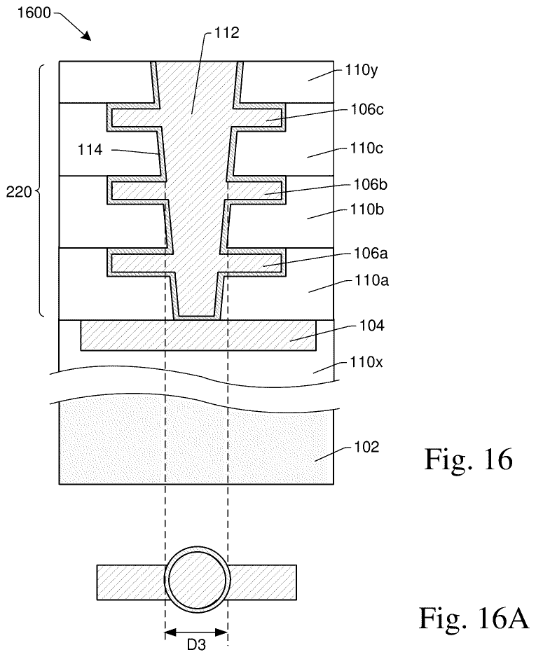

As shown in cross-sectional view 1600 of FIG. 16, a removal process is performed to remove excess conductive filling material 107 outside the widened deep opening 111′ (in FIG. 14) and to planarize top surfaces of the deep conductive via 112 and the exposed upper dielectric layer 110y. In this way, a conductive interconnect structure 220 including the lateral conductive layers (such as 106a, 106b, and 106c) and the deep conductive via 112 is created. Referring to FIG. 16A illustrating a top view of some embodiments of a portion of the integrated chip structure in FIG. 16, a profile of the deep conductive via 112 is round-shaped from the top view, and the deep conductive via 112 at the level of the second lateral conductive layer 106b has a diameter D3 greater than D1 at the level of the second lateral opening 105b (in FIG. 12A).

In this way, there is no need to reserve enclosure for the deep conductive via 112 landing on the conductive layers 106 (such as 106a, 106b, and 106c), thereby advantageously leading to improved self-alignment to enlarge process window. Thus, the odds for the produced semiconductor structure experiencing open or short issues are greatly reduced, even if the deep conductive via 112 has a slight overlap shift relative to the conductive layers 106.

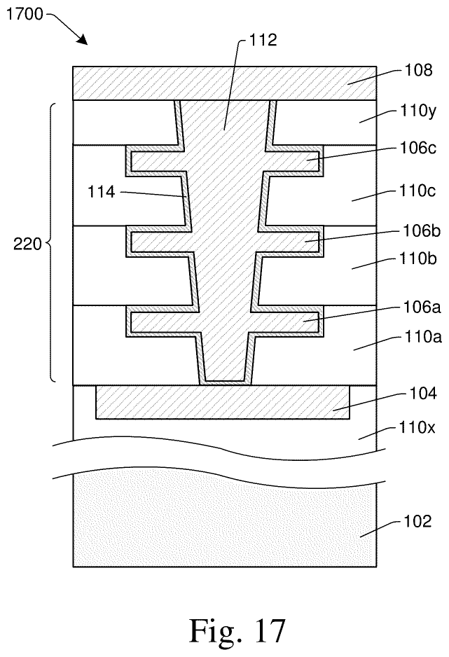

As shown in cross-sectional view 1700 of FIG. 17, an upper conductive layer 108 is formed overlaying the top surfaces of the deep conductive via 112 and the upper dielectric layer 110y. In some embodiments, the interconnect structure 220 is in electrical connection with the lower conductive layer 104 and the upper conductive layer 108 through the deep conductive via 112 thereof, thereby electrically connecting the lower conductive layer 104 and the upper conductive layer 108 together in FIG. 17. In other embodiments, the deep conductive via 112 is merely in electrical connection with the intermediate conductive layers (such as 106a, 106b, and 106c) and thus electrically connects them together (as shown in FIG. 17), but not in electrical connection with the lower conductive layer 104 and the upper conductive layer 108 (not shown).

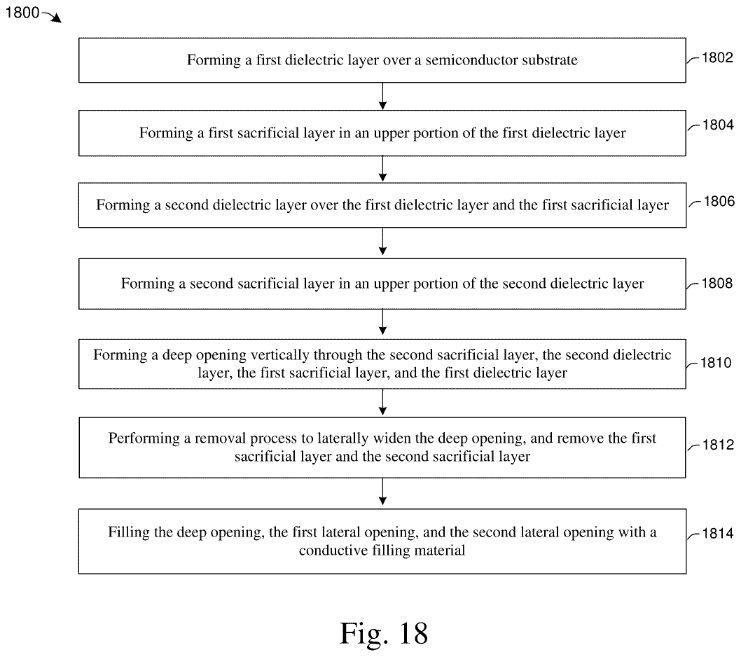

FIG. 18 illustrates a flow diagram of some embodiments of a method 1800 of forming an integrated chip structure having a deep via extending through multiple interconnect layers in FIG. 2A. While method 1800 is illustrated and described herein as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

At act 1802, a first dielectric layer 110a is formed over a semiconductor substrate 102. FIGS. 4-5 illustrate cross-sectional views 400-500 of some embodiments corresponding to act 1802.

At act 1804, a first sacrificial layer 103a is formed in an upper portion of the first dielectric layer 110a. FIGS. 6-8 illustrate cross-sectional views 600-800 of some embodiments corresponding to act 1804. Referring to e.g., FIGS. 6-8, a first recess 101a is formed in an upper portion of the first dielectric layer 110a, the first recess 101a is filled with a sacrificial material 103, and then the sacrificial material 103 outside the first recess 101a is removed. As such, the first sacrificial layer 103a is formed within an upper portion of the first dielectric layer 110a.

At act 1806, a second dielectric layer 110b is formed overlaying top surfaces of the first dielectric layer 110a and the first sacrificial layer 103a. FIG. 9 illustrates a cross-sectional view 900 of some embodiments corresponding to act 1806.

At act 1808, a second sacrificial layer 103b is formed in an upper portion of the second dielectric layer 110b. FIG. 10 illustrates a cross-sectional view 1000 of some embodiments corresponding to act 1808. In some embodiments, an additional dielectric layer (e.g., a third dielectric layer) 110c is formed overlaying top surfaces of the second dielectric layer 110b and the second sacrificial layer 103b, and an additional sacrificial layer (e.g., a third sacrificial layer) 103c is formed in an upper portion of the third dielectric layer 110c.

At act 1810, a deep opening 111 is formed vertically through e.g., the second sacrificial layer 103b, the second dielectric layer 110b, the first sacrificial layer 103a, and the first dielectric layer 110a. FIG. 12 illustrates a cross-sectional view 1200 of some embodiments corresponding to act 1810.

At act 1812, a removal process is performed to laterally widen the deep opening 111 to form a widened deep opening 111′, and laterally remove the first sacrificial layer 103a and the second sacrificial layer 103b that are laterally exposed by the deep opening 111 to form a first lateral opening 105a and a second lateral opening 105b. FIG. 13 illustrates a cross-sectional view 1300 of some embodiments corresponding to act 1812.

At act 1814, a conductive filling material 107 is filled into the widened deep opening 111′, the first lateral opening 105a, and the second lateral opening 105b to respectively form a deep conductive via 112, a first conductive layer, and a second conductive layer, wherein the deep conductive via, the first conductive layer, and the second conductive layer combinedly form an interconnect structure. FIG. 15 illustrates a cross-sectional view 1500 of some embodiments corresponding to act 1814. In some embodiments, additionally, prior to act 1814, a conductive liner 114 is deposited on inner surfaces of the widened deep opening 111′, the first lateral opening 105a, and the second lateral opening 105b by employing for example a deposition process (such as a PEALD process or a thermal ALD process) as shown in FIG. 14.

As such, an integrated chip structure with an interconnect structure 220 (in FIG. 16) including the conductive layers 106 and the deep conductive via 112 is created. Referring to FIG. 16A, the deep conductive via 112 has an enlarged diameter D3 e.g., at the level of the second conductive layer 106b. Thus, there is no need to reserve enclosure for the deep conductive via 112 landing on the conductive layers 106, thereby advantageously leading to improved self-alignment to enlarge process window.

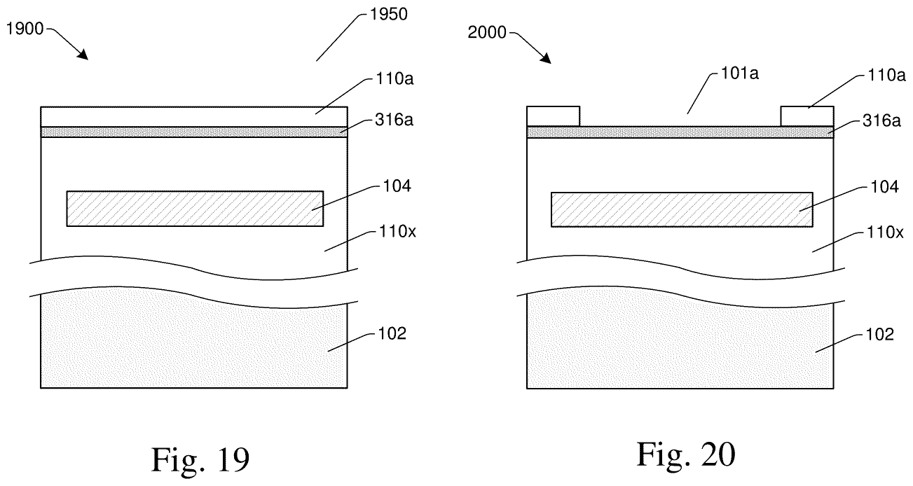

FIGS. 19-34 illustrate cross-sectional views of some embodiments to a method of forming an integrated chip structure having a deep via extending through multiple interconnect layers in FIG. 3A. Although FIGS. 19-34 are described in relation to a method, it will be appreciated that the structures disclosed in FIGS. 19-34 are not limited to such a method, but instead may stand alone as structures independent of the method.

As shown in cross-sectional view 1900 of FIG. 19, a semiconductor structure 1950 including a lower interlayer dielectric (ILD) 110x disposed over a substrate 102 and a lower conductive layer 104 disposed in the lower ILD 110x is provided. In some embodiments, a first etch stop layer (ESL) 316a is disposed over the lower ILD 110x, and a first intermediate ILD 110a is disposed over the first ESL 316a. In some embodiments, the lower ILD 110x and the first ILD 110a may include a dielectric material, such as silicon dioxide, carbon doped silicon oxide (SiCOH), phosphosilicate glass (PSG), borophosphosilicate glass (BPSG), borosilicate glass (BSG), fluorosilicate glass (FSG), undoped silicate glass (USG), and/or the like. In some embodiments, the first ESL 316a may include an oxide that is different from the material of the lower ILD 110x and the first ILD 110a.

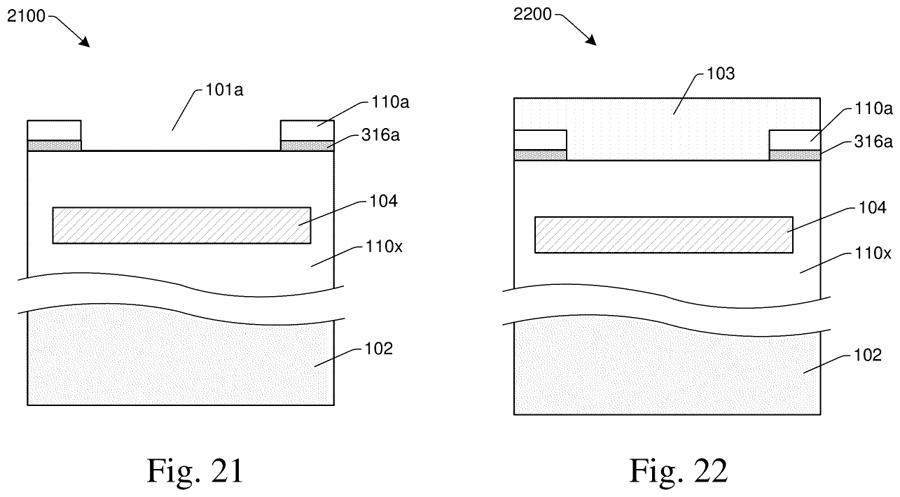

As shown in cross-sectional view 2000 of FIG. 20, in some embodiments, a first recess 101a is formed through the first intermediate ILD 110a by employing for example a dry etching process. Also as shown in cross-sectional view 2100 of FIG. 21, in some embodiments, the first recess 101a is further extended down through the first ESL 316a by employing for example a wet etching process. In other embodiments, the first recess 101a is formed through both the first intermediate ILD 110a and the first ESL 316a by employing a single etching process (such as a dry etching process or a wet etching process).

As shown in cross-sectional view 2200 of FIG. 22, the first recess 101a (in FIG. 21) is filled with a sacrificial material 103 by employing for example a deposition process (such as CVD, PVD, and the like). In some embodiments, the sacrificial material 103 can be poly-Si, a-Si, SiN, Ge, SiGe, AlOx, or oxide, and the like, and is different from the materials of the first intermediate ILD 110a, the first ESL 316a, and the lower ILD 110x.

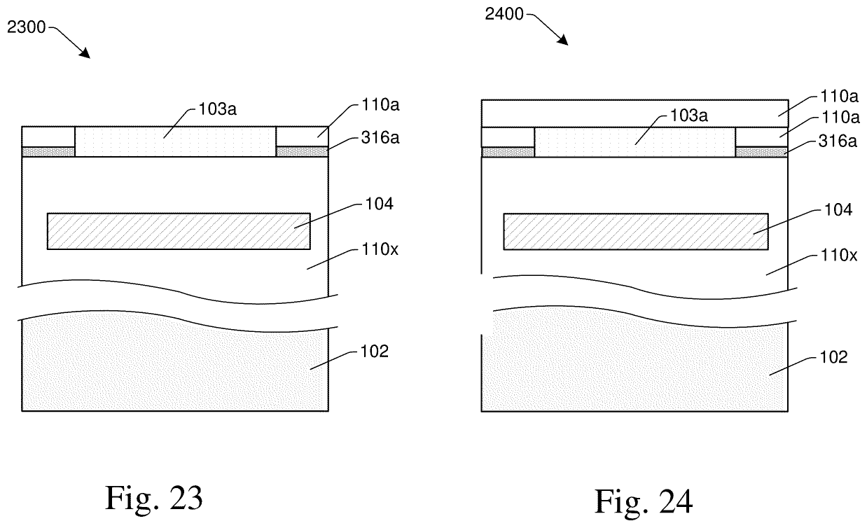

As shown in cross-sectional view 2300 of FIG. 23, the sacrificial material 103 outside the first recess 101a (in FIG. 22) is removed by employing for example a Chemical Mechanical Polishing (CMP) process, thereby forming a first sacrificial layer 103a. The top surfaces of the first sacrificial layer 103a and the first intermediate ILD 110a are planarized by the CMP process and thus co-planar.

As shown in cross-sectional view 2400 of FIG. 24, an additional material of the first intermediate ILD 110a is deposited overlaying the top surfaces of the first sacrificial layer 103a and the already-formed first intermediate ILD 110a, thereby increasing a thickness of the first intermediate ILD 110a.

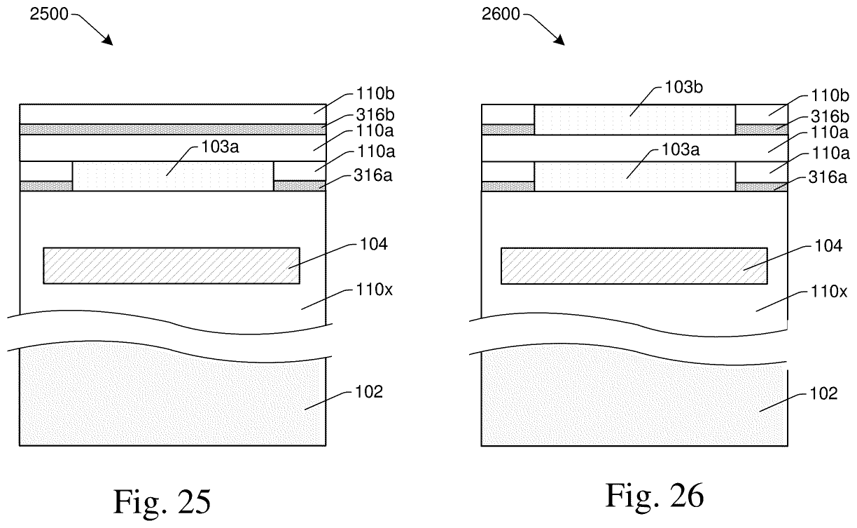

As shown in cross-sectional view 2500 of FIG. 25, similar to the processes in FIG. 19, a second ESL 316b is disposed over the first intermediate ILD 110a, and a second intermediate ILD 110b is disposed over the second ESL 316b. In some embodiments, the materials of the second intermediate ILD 110b and the first intermediate ILD 110a are the same, and in other embodiments, the materials of the second intermediate ILD 110b and the first intermediate ILD 110a are different. In some embodiments, the materials of the second ESL 316b and the first ESL 316a are the same, and in other embodiments, the materials of the second ESL 316b and the first ESL 316a are different.

As shown in cross-sectional view 2600 of FIG. 26, similar to the processes as shown in FIGS. 20-23, a second sacrificial layer 103b is formed extending through the second intermediate ILD 110b and the second ESL 316b.

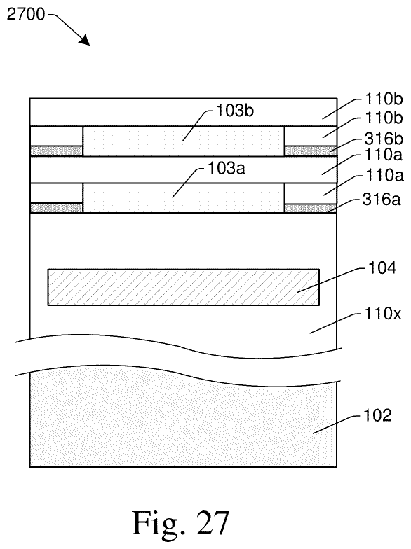

As shown in cross-sectional view 2700 of FIG. 27, similar to the process as shown in FIG. 24, an additional material of the second intermediate ILD 110b is deposited overlaying the top surfaces of the second sacrificial layer 103b and the already-formed second intermediate ILD 110b, thereby increasing a thickness of the second intermediate ILD 110b.

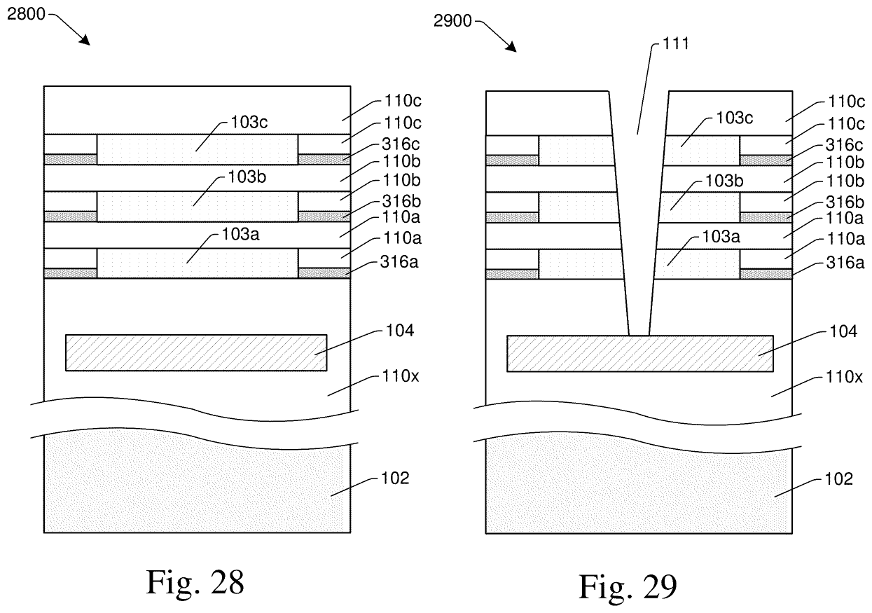

As shown in cross-sectional view 2800 of FIG. 28, similar to the processes as shown in FIGS. 20-24, a third ESL 316c is disposed over the second intermediate ILD 110b, a third intermediate ILD 110c is then disposed over the third ESL 316c, a third sacrificial layer 103c is formed extending through the third intermediate ILD 110c and the third intermediate ESL 316c, and an additional material of the third intermediate ILD 110c is then deposited overlaying the top surfaces of the third sacrificial layer 103c and the already-formed third intermediate ILD 110c, thereby increasing a thickness of the third intermediate ILD 110c.

As shown in cross-sectional view 2900 of FIG. 29, a deep opening 111 is formed vertically through e.g., the third intermediate ILD 110c, the third sacrificial layer 103c, the second intermediate ILD 110b, the second sacrificial layer 103b, the first intermediate ILD 110a, and the first sacrificial layer 103a by employing for example a lithography process followed by an anisotropic etching process (such as a dry etching process). In some embodiments, the deep opening 111 stops at the lower conductive layer 104, and exposes the lower conductive layer 104.

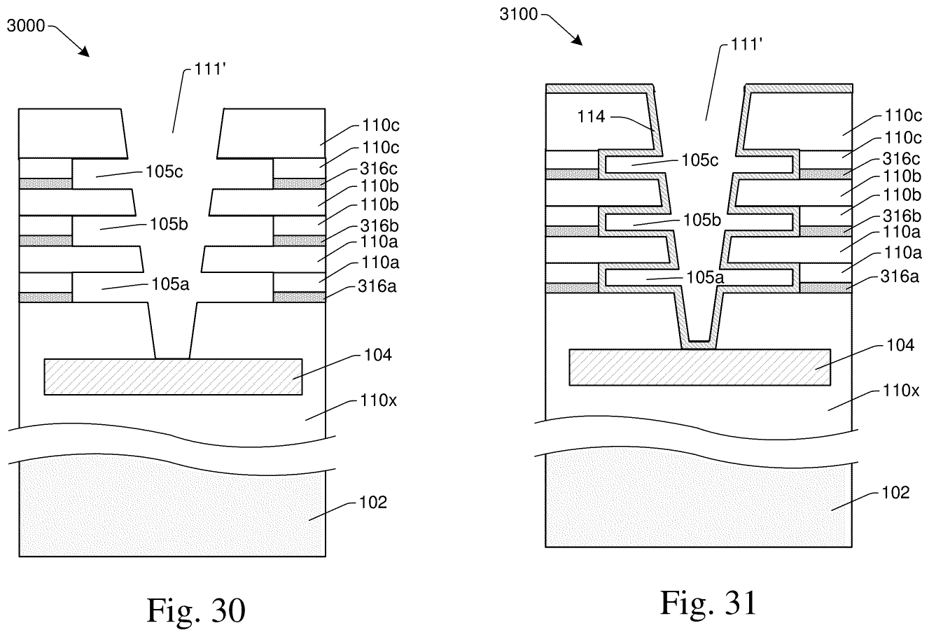

As shown in cross-sectional view 3000 of FIG. 30, a removal process is performed to laterally widen the deep opening 111 in FIG. 29 to form a widened deep opening 111′, and to laterally remove all of the sacrificial layers 103a-103c exposed by the deep opening 111 in FIG. 29 to respectively form lateral openings 105a-105c, by employing for example an isotropic etching process (such as a wet etching process). As such, the lateral openings 105a-105c and the widened deep opening 111′ are formed open to each other, thereby combinedly creating a spatially-connected chamber.

As shown in cross-sectional view 3100 of FIG. 31, a conductive liner 114 is formed on inner surfaces of the spatially-connected chamber including the widened deep opening 111′ and the lateral openings 105a-105c in FIG. 30 by employing for example a deposition process (such as a PEALD process or a thermal ALD process). In some embodiments, the conductive liner 114 includes a seed material of TiN or TaN.

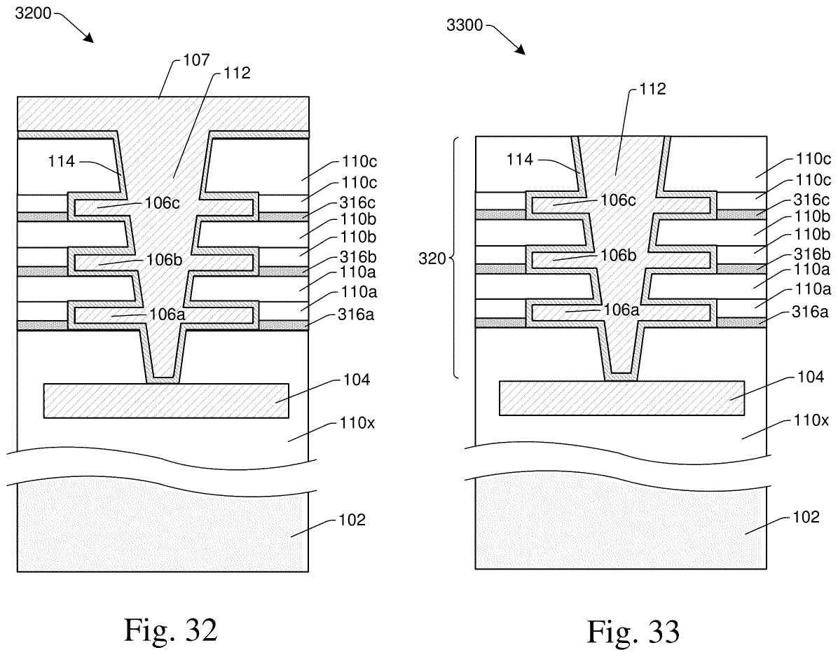

As shown in cross-sectional view 3200 of FIG. 32, a conductive filling material 107 (such as W or Cu) is filled into the spatially-connected chamber (in FIG. 31) including the lateral openings 105a-105c and the widened deep opening 111′ by employing for example a deposition process (such as CVD, PVD, and the like) to respectively form lateral conductive layers 106a-106c and a deep conductive via 112.

As shown in cross-sectional view 3300 of FIG. 33, a removal process is performed to remove excessive conductive filling material 107 outside the widened deep opening 111′ in FIG. 32 and to planarize top surfaces of the deep conductive via 112 and the third intermediate ILD 110c. In this way, a conductive interconnect structure 320 including the lateral conductive layers (e.g., 106a-106c) and the deep conductive via 112 is created.

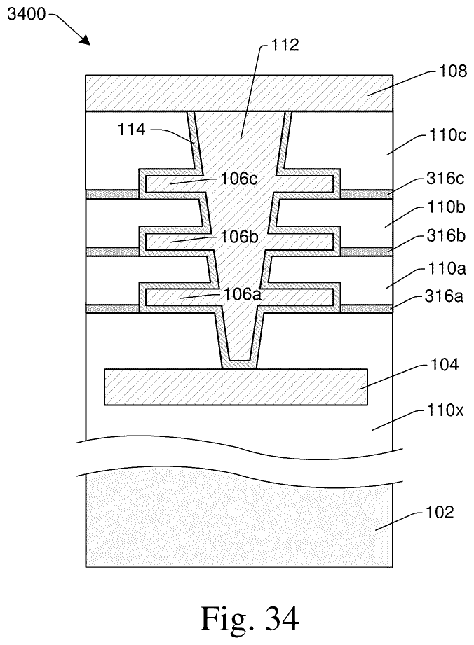

As shown in cross-sectional view 3400 of FIG. 34, an upper conductive layer 108 is formed overlaying the top surfaces of the deep conductive via 112 and the third intermediate ILD 110c. In some embodiments, the interconnect structure 320 is in electrical connection with the lower conductive layer 104 and the upper conductive layer 108 through the deep conductive via 112 thereof, thereby electrically connecting them together in FIG. 34. In other embodiments, the deep conductive via 112 is in electrical connection with the lateral conductive layers 106a-106c and thus electrically connects them together (as shown in FIG. 34), but is not in electrical connection with the lower conductive layer 104 and the upper conductive layer 108 (not shown).

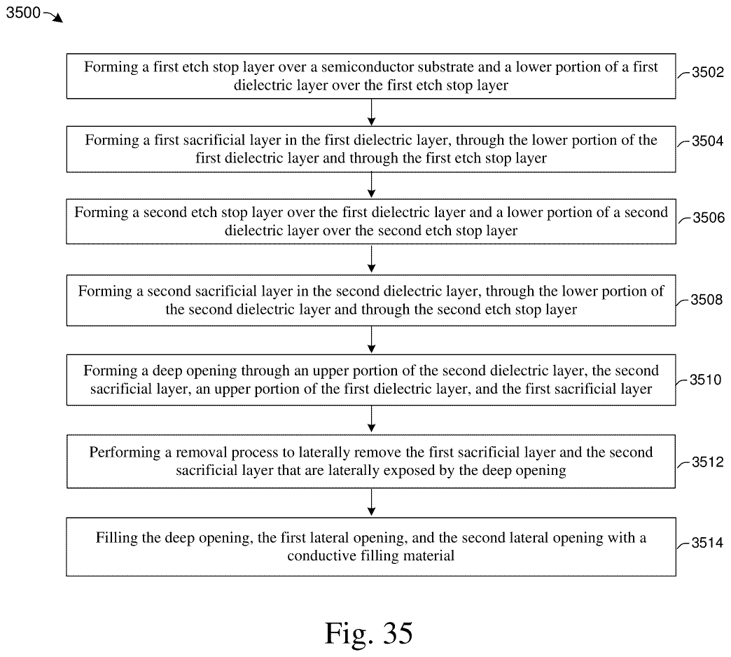

FIG. 35 illustrates a flow diagram of some embodiments of a method 3500 for manufacturing an integrated chip structure having a deep via extending through multiple interconnect layers in FIG. 3A. While method 3500 is illustrated and described herein as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

At act 3502, a first etch stop layer (ESL) 316a over a semiconductor substrate 102 and a first intermediate ILD 110a over the first ESL 316a are sequentially formed. FIG. 19 illustrates a cross-sectional view 1900 of some embodiments corresponding to act 3502. In some embodiments, a lower ILD 110x is disposed over the substrate 102, a lower conductive layer 104 is disposed in the lower ILD 110x, and the first ESL 316a is disposed over a top surface of the lower ILD 110x.

At act 3504, a first sacrificial layer 103a is formed in the first intermediate ILD 110a, through a lower portion of the first intermediate ILD 110a and through the first ESL 316a. FIG. 20-24 illustrate cross-sectional views 2000-2400 of some embodiments corresponding to act 3504. Referring to FIGS. 20-24, a first recess 101a is formed through the first intermediate ILD 110a, the first recess 101a is filled with a sacrificial material 103, the sacrificial material 103 outside the first recess 101a is removed, and then an additional material of the first intermediate ILD 110a is deposited overlaying the top surfaces of the first sacrificial layer 103a and the already-formed first intermediate ILD 110a, thereby increasing a thickness of the first intermediate ILD 110a. As such, the first sacrificial layer 103a is formed in the first intermediate ILD 110a.

At act 3506, a second ESL 316b over the first intermediate ILD 110a and a second intermediate ILD 110b over the second ESL 316b are sequentially formed. FIG. 25 illustrates a cross-sectional view 2500 of some embodiments corresponding to act 3506.

At act 3508, a second sacrificial layer 103b is formed in the second intermediate ILD 110b, through a lower portion of the second intermediate ILD 110b and through the second ESL 316b. FIGS. 25-27 illustrate cross-sectional views 2500-2700 of some embodiments corresponding to act 3508. Additionally, a third sacrificial layer 103c can be formed in a third intermediate ILD 110c, through a lower portion of the third intermediate ILD 110c and through the third ESL 316c in some embodiments as shown in FIG. 28.

At act 3510, a deep opening 111 is formed through e.g., an upper portion of the second intermediate ILD 110b, the second sacrificial layer 103b, an upper portion of the first intermediate ILD 110a, and the first sacrificial layer 103a. FIG. 29 illustrates a cross-sectional view 2900 of some embodiments corresponding to act 3510.

At act 3512, a removal process is performed to laterally widen the deep opening 111 to form a widened deep opening 111, and to laterally remove e.g., the first sacrificial layer 103a and the second sacrificial layer 103b that are laterally exposed by the deep opening 111 to respectively form e.g., a first lateral opening 105a and a second lateral opening 105b. The lateral openings 105a-105c and the widened deep opening 111′ are formed open to each other, and thus combinedly create a spatially-connected chamber. FIG. 30 illustrates cross-sectional view 3000 of some embodiments corresponding to act 3512. In some embodiments, as shown in FIG. 31, after creating the spatially-connected chamber, a conductive liner 114 is deposited on inner surfaces of the widened deep opening 111′, the first lateral opening 105a, and the second lateral opening 105b.

At act 3514, the widened deep opening 111′, the first lateral opening 105a, and the second lateral opening 105b are filled with a conductive filling material 107 to respectively form a deep conductive via 112, a first conductive layer 106a, and a second conductive layer 106b. FIGS. 32-33 illustrate cross-sectional views 3200-3300 of some embodiments corresponding to act 3514. As shown in FIG. 33, in some embodiments, the deep conductive via 112, the first conductive layer 106a, and the second conductive layer 106b combinedly form an interconnect structure 320. In some embodiments, the deep conductive via 112 protrudes downwards from the first conductive layer 106a and upwards from the second conductive layer 106b.

FIG. 36 illustrates a cross-sectional view of some additional embodiments of an integrated chip structure 3600 having a deep via extending through multiple interconnect layers. The integrated chip structure 3600 comprises a semiconductor device 3602 disposed within a substrate 102. In some embodiments, the semiconductor device 3602 may comprise a transistor device (e.g., a planar FET, a Fin-FET, a gate all around FET, a complimentary FET (C-FET), and/or the like). In some embodiments, the transistor device may comprise a gate structure 3604 disposed over a channel region arranged between source/drain regions 3606.

The semiconductor device 3602 is coupled to a lower conductive layer 104 by way of a lower via 3608 disposed within an ILD structure 110 overlying the substrate 102. In some embodiments, the lower via 3608 may comprise a conductive contact physically contacting one of the source/drain regions 3606 of the transistor device. The lower via 3608 has a first width. A deep conductive via 112 is arranged over the lower conductive layer 104. The deep conductive via 112 vertically extends past one or more intermediate conductive layers (or intermediate interconnect layers) 106 to contact an upper conductive layer 108 that is directly over the lower conductive layer 104. The deep via 112 has a widened second width, which allows for the deep conductive via 112 to provide for a relatively low resistance contact between the lower conductive layer 104 and the upper conductive layer 108. In some embodiments, the sidewalls of the deep conductive via 112 vertically extend as shown in FIG. 36. In other embodiments, the sidewalls of the deep conductive via 112 tilt from the vertical direction as shown in FIG. 1A.

The upper conductive layer 108 is further coupled to a bonding structure 3610. In some embodiments, the bonding structure 3610 may comprise an under bump metallization (UBM) structure 3612 and an overlying conductive bonding structure 3614 is arranged over the UBM structure 3612. In some embodiments, the conductive bonding structure 3614 may comprise a solder bump. In other embodiments, the bonding structure 3610 may alternatively and/or additionally comprise a redistribution layer, a bond pad, and/or the like.

FIG. 37 illustrates a cross-sectional view of some additional embodiments of an integrated chip structure 3700 having a deep via extending through multiple interconnect layers. The integrated chip structure 3700 includes a semiconductor device 3602 arranged along a first side 102a of a substrate 102. In some embodiments, the semiconductor device 3602 comprises a transistor device.

A front-side ILD structure 3702 is arranged along the first side 102a of the substrate 102. The front-side ILD structure 3702 may comprise a plurality of ILD layers stacked onto one another. A plurality of front-side interconnect layers 3704 are disposed within the front-side ILD structure 3702. In some embodiments, the plurality of front-side interconnect layers 3704 may comprise conductive contacts, interconnect wires, interconnect vias, and/or the like. In some embodiments, the front-side ILD structure 3702 may also surround a lower conductive layer 104 that is within a lower ILD layer within the front-side ILD structure 3702.

An ILD structure 110 is arranged along a second side 102b of the substrate 102 opposing the first side 102a of the substrate 102. The ILD structure 110 surrounds a plurality of conductive layers 106-108 including one or more intermediate interconnect conductive 106 and an upper conductive layer 108. The ILD structure 110 also surrounds a deep conductive via 112, which extends between the lower conductive layer 104 and the upper conductive layer 108. The deep conductive via 112 vertically extends from within the ILD structure 110, through the substrate 102 and into the front-side ILD structure 3702. In some embodiments, the sidewalls of the deep conductive via 112 vertically extend as shown in FIG. 37. In other embodiments, the sidewalls of the deep conductive via 112 tilt from the vertical direction as shown in FIG. 1A.

In some embodiments, the plurality of conductive layers 106-108 are configured to deliver power from a package to the semiconductor device 3602. For example, the upper conductive layer 108 may comprise a power rail configured to deliver power (e.g., VDD, VSS, etc.) and/or ground signals. Delivering power to the semiconductor device 3602 using the plurality of interconnect layers 106-108 on the second side 102b of the substrate 102 frees space on the first side 102a of the substrate 102 for electrical routing between semiconductor devices. Furthermore, it may enable power delivery to the semiconductor device 3602 through wider, less resistive metal lines, without electrons needing to travel through a complex BEOL stack. This approach may to benefit IR drop, improve power delivery performance, reduce routing congestion in the BEOL, and/or the like.

FIG. 38 illustrates a cross-sectional view of some additional embodiments of an integrated chip structure 3800 having a deep via extending through multiple interconnect layers.

The integrated chip structure 3800 comprises a plurality of chiplets 3802-3804 laterally surrounded by a molding compound 3806. In various embodiments, the molding compound 3806 may comprise a polymer, a thermosetting plastic, a resin, and/or the like. The molding compound 3806 may laterally separate the plurality of chiplets 3802-3804 from one another and from one or more conductive pillars 3808 extending through the molding compound 3806. The chiplets 3802-3804 are electrically coupled to a redistribution structure 3810 disposed over the molding compound 3806 by way of back-end-of-line (BEOL) interconnect structures. In some embodiments, the plurality of chiplets 3802-3804 and the molding compound 3806 may be disposed over an underlying carrier substrate or interposer substrate (not shown). In some embodiments, the one or more conductive pillars 3808 may be coupled to the underlying carrier substrate or interposer substrate by way of one or more conductive bumps 3811 (e.g., micro-bumps).

The redistribution structure 3810 comprises a plurality of conductive redistribution interconnect structures that electrically couple the plurality of chiplets 3802-3804 to one another, to the conductive pillars 3808, to one or more additional chiplets 3812, and/or the one or more bonding structures 3814. In some embodiments, the conductive redistribution interconnect structures each includes a lower conductive layer 104, one or more intermediate conductive layers 106, an upper conductive layer 108, and a deep conductive via 112 extending through the one or more intermediate conductive layers 106 and coupled to the lower conductive layer 104 and the upper conductive layer 108. The deep conductive via 112 enables the redistribution structure 3810 to be formed at a lower cost and with a higher throughput.

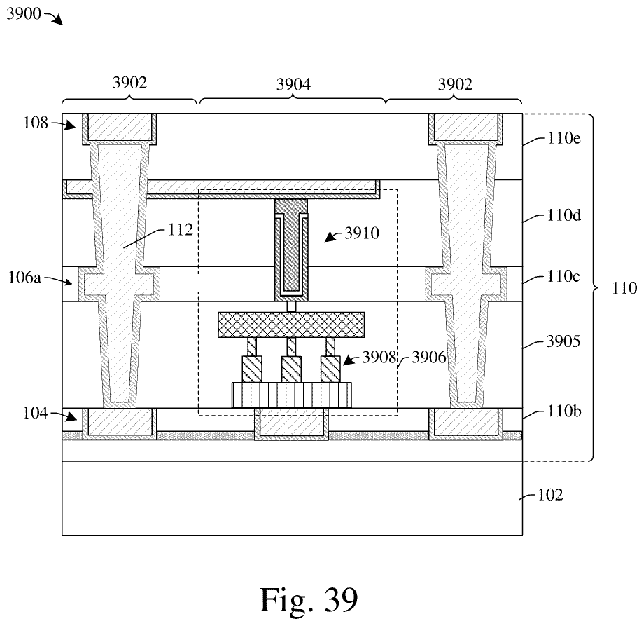

FIG. 39 illustrates a cross-sectional view of some additional embodiments of an integrated chip structure 3900 having a deep via extending through multiple interconnect layers. The integrated chip structure 3900 includes a substrate 102 having a logic region 3902 and a memory region 3904. An ILD structure 110 is disposed over the substrate 102 within the logic region 3902 and the memory region 3904. Within the logic region 3902, the ILD structure 110 surrounds a plurality of conductive layers including a lower conductive layer 104, one or more intermediate conductive layers 106 (e.g., 106a), and an upper conductive layer 108. Within the memory region 3904, the ILD structure 110 further surrounds a plurality of memory devices 3906.

The plurality of memory devices 3906 include a plurality of transistor devices 3908 respectively coupled to a data storage element 3910 configured to store a first data state (e.g., a logical ‘0’) or a second a second data state (e.g., a logical ‘1’). In some embodiments, the data storage element 3910 may comprise a capacitor. In other embodiments, the data storage element 3910 may comprise a resistive random access memory device (RRAM), a ferroelectric random access memory (FeRAM) device, a magneto resistive random access memory (MRAM) device, a phase change random access memory (PCRAM) device, and/or the like.

A deep conductive via 112 extends through the one or more intermediate interconnect layers 106 within the logic region 3902. The deep conductive via 112 vertically extends past the plurality of transistor devices 3908 and the data storage element 3910.

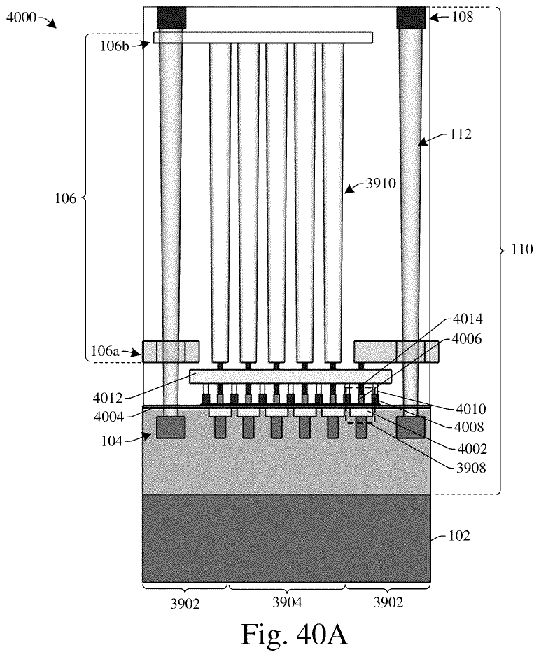

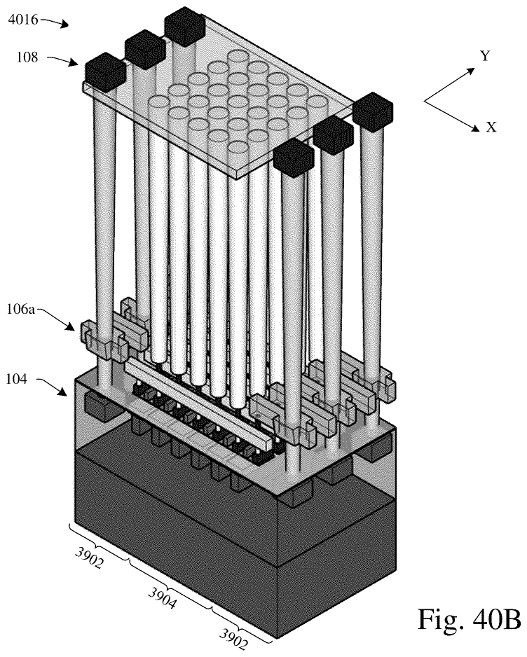

FIG. 40A illustrates a cross-sectional view of some additional embodiments of an integrated chip structure 4000 having deep via extending through multiple interconnect layers. The integrated chip structure 4000 includes a substrate 102 having a logic region 3902 and a memory region 3904. An ILD structure 110 is disposed over the substrate 102 within the logic region 3902 and the memory region 3904. Within the logic region 3902, the ILD structure 110 surrounds a plurality of interconnect layers including a lower conductive layer 104, one or more intermediate interconnect layers 106, and an upper conductive layer 108. Within the memory region 3904, the ILD structure 110 further surrounds a plurality of memory devices (e.g., a capacitor, an MRAM device, a ReRAM device, etc.).

The memory devices include a transistor device 3908 coupled to a data storage element 3910. The transistor device 3908 includes a channel layer 4004 disposed over a gate structure 4002 within the lower conductive layer 104. In some embodiments, a gate dielectric (not shown) may separate the gate structure 4002 from the channel layer 4004. A source contact 4006 and a drain contact 4008 are disposed over the channel layer 4004. In some embodiments, the channel layer 4004 may comprise an oxide semiconductor, a high-k dielectric layer, or the like. A bit-line via 4010 extends from the drain contact 4008 to a bit-line 4012 that laterally extends past a plurality of memory device vias 4014 that extend from the source contact 4006 to the data storage elements 3910.

In some embodiments, one of the memory device vias 4014 couples a source contact 4006 to an intermediate interconnect that extends from within the memory region 3904 to within the logic region 3902 on a first intermediate conductive layer 106a. In some embodiments, the data storage elements 3910 extend from the plurality of memory device vias 4014 to an intermediate interconnect that extends from within the memory region 3904 to within the logic region 3902 on a second intermediate conductive layer 106b. A deep conductive via 112 extends through the one or more intermediate conductive layers 106 within the logic region 3902. The deep conductive via 112 vertically extends past the plurality of transistor devices 3908 and the data storage element 3910.

FIG. 40B illustrates a three-dimensional view 4016 of the integrated chip structure of FIG. 40A. The memory devices are arranged in a memory array extending in a first direction (X direction) and along a second direction (Y direction) perpendicular to the first direction. Rows of the memory array extending along the first direction are coupled to an intermediate conductive layer 106a that extends into the logic region 3902.

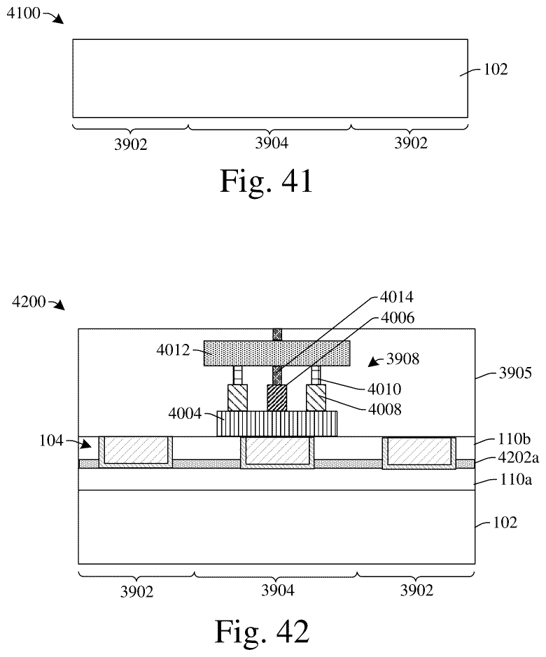

FIGS. 41-50 illustrate cross-sectional views 4100-4900 of some additional embodiments to a method of forming an integrated chip structure (e.g., as shown in FIGS. 40A-40B) having a deep via extending through multiple interconnect layers. Although the structures shown in the cross-sectional views 4100-4900 of FIGS. 41-49 are described with reference to a method, it will be appreciated that the structures shown in the cross-sectional views 4100-4900 of FIGS. 41-49 are not limited to the method of formation but rather may stand alone separate of the method.

As shown in cross-sectional view 4100 of FIG. 41, a substrate 102 is provided. In various embodiments, the substrate 102 may be any type of substrate (e.g., silicon, SiGe, SOI, etc.), such as a semiconductor wafer, as well as any other type of semiconductor and/or epitaxial layers, associated therewith. The substrate comprises a logic region 3902 and a memory region 3904.

As shown in cross-sectional view 4200 of FIG. 42, a lower etch stop layer (ESL) 4202a is formed over the substrate 102 and a lower interlayer dielectric (ILD) 110b is formed over the lower ESL 4202a. In some embodiments, the lower ESL 4202a and the lower ILD 110b may be formed by one or more deposition processes (e.g., a PVD process, a CVD process, a PE-CVD process, and/or the like). A lower conductive layer 104 is formed within the lower ILD 110b. In some embodiments, the lower conductive layer 104 may be formed using a damascene process.

After formation of the lower conductive layer 104, one or more transistor devices 3908 are formed within a device ILD structure 3905. The one or more transistor devices 3908 may be formed to comprise source/drain contacts disposed along opposing sides of a channel layer. In some embodiments, a gate structure may be formed on the lower interconnect layer and a gate dielectric may be formed on the gate structure. A channel layer is subsequently formed on the gate dielectric, and source/drain contacts are formed on the channel layer.

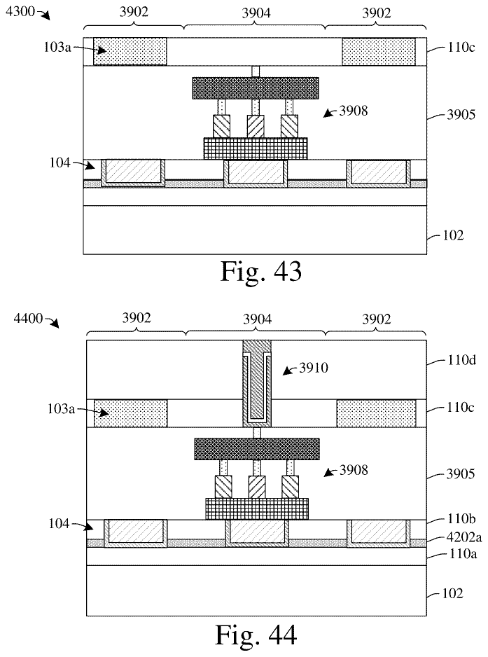

As shown in cross-sectional view 4300 of FIG. 43, a first intermediate conductive layer 106a is formed within a first intermediate ILD 110c formed over the device ILD structure 3905. In some embodiments, the first sacrificial layer 103a may be formed using a damascene process.

As shown in cross-sectional view 4400 of FIG. 44, one or more data storage elements 3910 are formed within the first intermediate ILD 110c and a second intermediate ILD 110d.

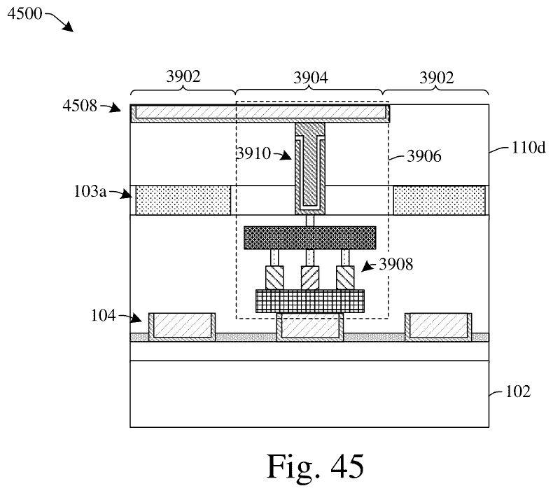

As shown in cross-sectional view 4500 of FIG. 45, an intermediate interconnect layer 4508 is formed within the ILD 110d. A thickness of the ILD 110d is subsequently increased to cover the intermediate interconnect layer 4508.

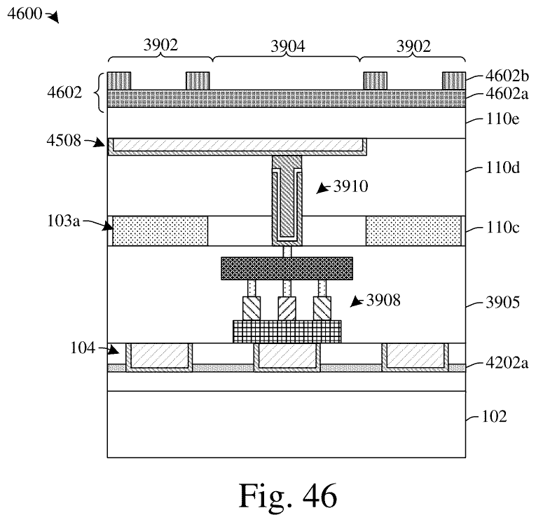

As shown in cross-sectional view 4600 of FIG. 46, a masking structure 4602 is formed over the ILD 110d. In some embodiments, the masking structure may comprise a hard mask layer 4602a and a photoresist layer 4602b disposed over the hard mask layer 4602a.

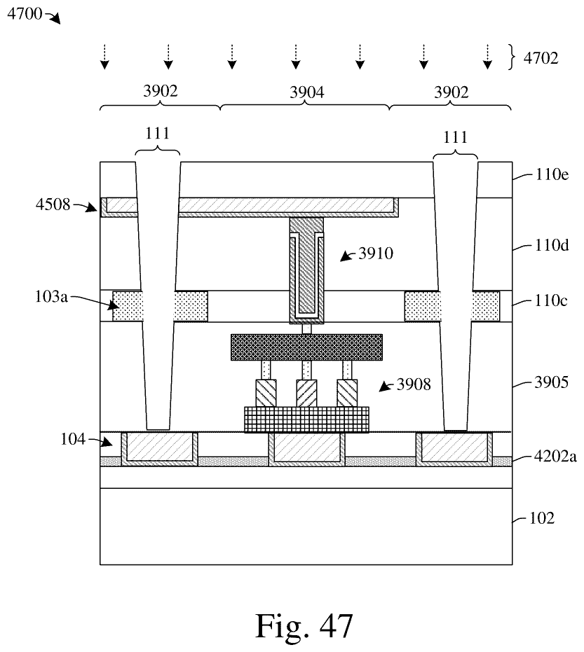

As shown in cross-sectional view 4700 of FIG. 47, a patterning process is subsequently performed on the ILDs 110c-110e. The patterning process removes parts of the ILDs 110c-110e to form a deep opening 111 through e.g., the first sacrificial layer 103a and the intermediate interconnect layer 4508. In some embodiments, the deep opening 111 may have a first width. In some embodiments, the patterning process may comprise an etching process that selectively exposes the intermediate ILDs 110c-110e to an etchant 4702 according to a mask formed over the intermediate ILDs 110c-110e.

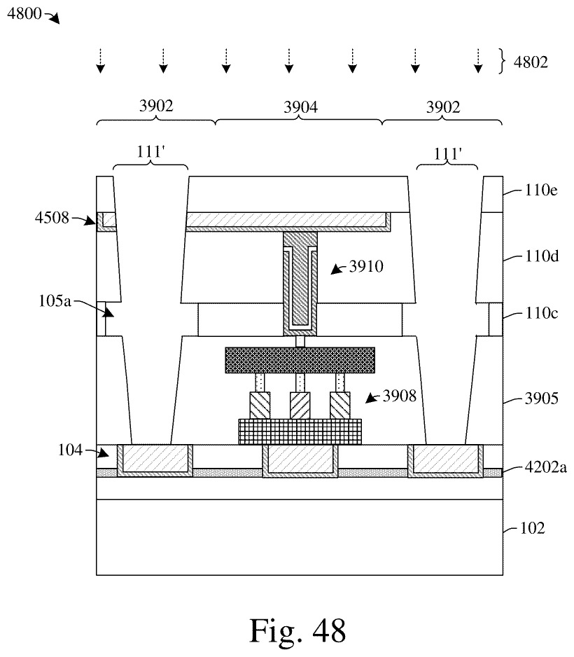

As shown in cross-sectional view 4800 of FIG. 48, a lateral etching process is performed on the intermediate ILDs 110c-110e to increase a width of the opening (e.g., 111) to form a widened deep opening 111', and laterally remove the first sacrificial layer 103a to form a first lateral opening 105a by using a wet etchant 4802. The widened deep opening 111′ and the first lateral opening 105a are open to each other and thus form a spatially-connected chamber.

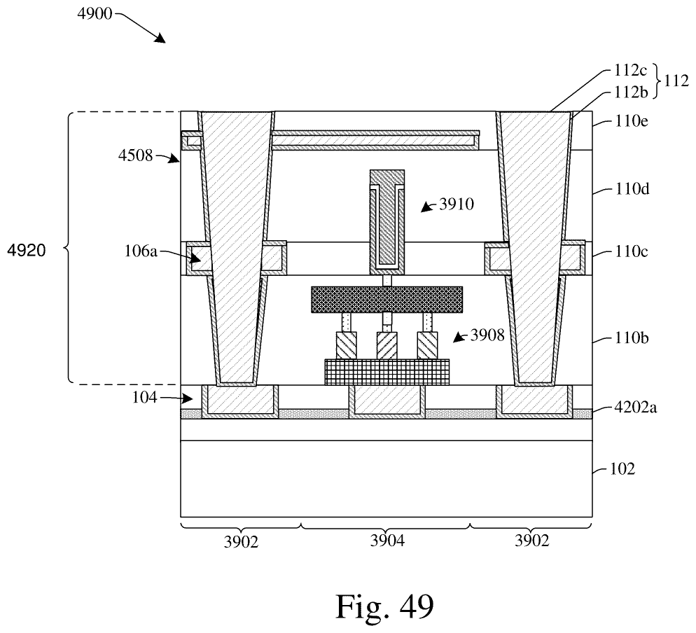

As shown in cross-sectional view 4900 of FIG. 49, a via barrier 112b is formed within the widened deep opening 111′ and the first lateral opening 105a in FIG. 48, and then a via conductive core 112c is formed on the via barrier 112b within the widened deep opening 111′ and the first lateral opening 105a in FIG. 48. A planarization process (e.g., a chemical mechanical planarization (CMP) process) is performed to remove parts of the via barrier 112b and the via conductive core 112c that are over the intermediate ILDs 110c-110e. As such, the deep conductive via 112 and a first conductive layer 106a are formed, thereby combinedly creating an interconnect structure 4920.

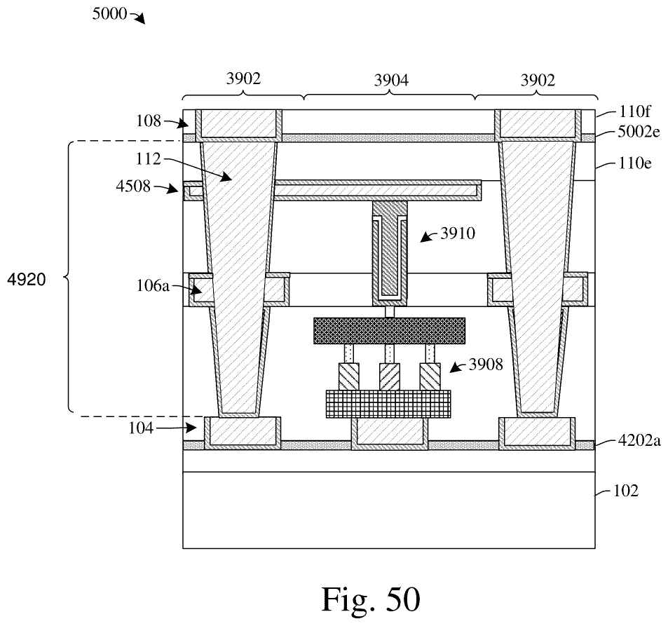

As shown in cross-sectional view 5000 of FIG. 50, an upper ESL 5002e is formed over the intermediate ILDs 110c-110e and an upper ILD 110f is formed over the upper ESL 402e. An upper conductive layer 108 is formed within the upper ILD 110f. In some embodiments, the upper ESL 5002e and the upper ILD 110f may be respectively formed by one or more deposition processes (e.g., a PVD process, a CVD process, a PE-CVD process, and/or the like). In some embodiments, the upper conductive layer 108 may be formed by a damascene process. In this way, the deep conductive via 112 of the interconnect structure 4920 can advantageously connect the lower conductive layer 104 and the upper conductive layer 108 with a low resistance at least due to the widened width of the widened deep conductive via 112.

Accordingly, in some embodiments, a semiconductor structure is provided. The semiconductor structure includes an interconnect structure disposed within a dielectric layer. The interconnect structure includes a first conductive layer extending in a first lateral direction, and vertically between a lower conductive layer and an upper conductive layer; and a deep conductive via extending through the first conductive layer in a vertical direction, from the lower conductive layer to the upper conductive layer. The deep conductive via and the first conductive layer correspond to different portions of a conductive filling material of the interconnect structure, and the conductive filling material is continuous.

In some embodiments, the interconnect structure further includes a second conductive layer extending in the first lateral direction, and vertically between the first conductive layer and the upper conductive layer. The deep conductive via extends through the second conductive layer in the vertical direction and contacts the second conductive layer.

In some embodiments, a conforming conductive liner is disposed between the conductive filling material and the dielectric layer. In some embodiments, an inner surface of the conductive liner interfacing the conductive filling material extends within the deep conductive via substantially in the vertical direction and is substantially smooth and continuous. In some embodiments, the conductive filling material may be TiN, W, Ru, TaN, or Cu, or may be one of other metal materials, and the conductive liner comprises a seed material that is TiN or TaN and is different from the filling conductive material.

In some embodiments, a top layout of the deep conductive via is round-shaped or slit-shaped from a top view. In some embodiments, wherein a width of the deep conductive via at a level of the first conductive layer is greater than a width of the first conductive layer in a second lateral direction perpendicular to the first lateral direction.

In some embodiments, the interconnect structure is disposed on a frontside of a semiconductor substrate of a semiconductor die, and a semiconductor device is arranged on the frontside of the semiconductor substrate between the semiconductor substrate and the interconnect structure. In some embodiments, the semiconductor structure further includes a plurality of IC chips embedded in a molding compound, the interconnect structure overlying and being electrically coupled to the plurality of IC chips. In some embodiments, the interconnect structure is disposed on a backside of a semiconductor substrate of a semiconductor die, and a semiconductor device is on a frontside of the semiconductor substrate opposite the backside.

In other embodiments, a method of manufacturing an integrated chip structure is provided. The method includes forming a first dielectric layer over a semiconductor substrate; forming a first sacrificial layer in an upper portion of the first dielectric layer; forming a deep opening vertically through the first sacrificial layer and the first dielectric layer; performing a removal process to laterally widen the deep opening, and remove the first sacrificial layer laterally exposed by the deep opening to respectively form a first lateral opening; and filling the deep opening and the first lateral opening with a conductive filling material to respectively form a deep conductive via and a first conductive layer. The deep conductive via and the first conductive layer form an interconnect structure.

In some embodiments, prior to filling the deep opening, a conductive liner layer is deposited on inner surfaces of the deep opening and the first lateral opening. In some embodiments, performing the removal process includes performing a lateral wet etching. In some embodiments, the method further includes forming a second dielectric layer over the first dielectric layer and the first conductive layer, and forming a second conductive layer in an upper portion of the second dielectric layer and in contact with the deep conductive via.

In some embodiments, forming the first sacrificial layer includes forming a first recess in the upper portion of the first dielectric layer, filling a sacrificial material in the first recess, and removing the sacrificial material outside the first recess. In some embodiments, forming the second sacrificial layer includes forming a second recess in the upper portion of the second dielectric layer, filling a sacrificial material in the second recess, and removing the sacrificial material outside the second recess.

In yet other embodiments, a method of manufacturing an integrated chip structure is provided. The method includes forming a first etch stop layer over a semiconductor substrate; forming a lower portion of a first dielectric layer over the first etch stop layer; forming a first sacrificial layer in the first dielectric layer, through the lower portion of the first dielectric layer and through the first etch stop layer; forming a second etch stop layer over the first dielectric layer; forming a lower portion of a second dielectric layer over the second etch stop layer; forming a second sacrificial layer in the second dielectric layer, through the lower portion of the second dielectric layer and through the second etch stop layer; forming a deep opening through an upper portion of the second dielectric layer, the second sacrificial layer, an upper portion of the first dielectric layer, and the first sacrificial layer; performing a removal process to laterally remove the first sacrificial layer and the second sacrificial layer that are laterally exposed by the deep opening to respectively form a first lateral opening and a second lateral opening and to laterally widen the deep opening; and filling the deep opening, the first lateral opening, and the second lateral opening with a conductive filling material to respectively form a deep conductive via, a first conductive layer, and a second conductive layer.

In some embodiments, forming the first sacrificial layer in the first dielectric layer includes forming the lower portion of the first dielectric layer over the first etch stop layer; forming a first recess through the lower portion of the first dielectric layer and the first etch stop layer; filling a sacrificial material in the first recess; removing the sacrificial material outside the first recess; and forming the upper portion of the first dielectric layer overlaying the first sacrificial layer and the lower portion of the first dielectric layer.

In some embodiments, forming the first recess includes forming a first portion of the first recess through the lower portion of the first dielectric layer by a first etching process that stops on the first etch stop layer; and forming a second portion of the first recess through the first etch stop layer by a second etching process. In some embodiments, the deep conductive via, the first conductive layer, and the second conductive layer form an interconnect structure, and the deep conductive via is formed to protrude from a lower surface of the first conductive layer and from an upper surface of the second conductive layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
an interconnect structure disposed within a dielectric layer, and comprising:
a first lateral conductive portion extending in a first lateral direction, and vertically between a lower conductive layer and an upper conductive layer; and
a vertical conductive portion extending in a vertical direction, from the lower conductive layer to the upper conductive layer, and laterally contacting the first lateral conductive portion in the first lateral direction.

2. The semiconductor structure of claim 1, wherein the interconnect structure further comprises a second lateral conductive portion extending in the first lateral direction, and vertically between the first lateral conductive portion and the upper conductive layer, and wherein the vertical conductive portion extends in the vertical direction and contacts the second lateral conductive portion in the first lateral direction.

3. The semiconductor structure of claim 1, wherein a conforming conductive liner is disposed between the conductive filling material and the dielectric layer.

4. The semiconductor structure of claim 3, wherein an inner surface of the conductive liner interfacing the conductive filling material extends within the vertical conductive portion substantially in the vertical direction and is substantially smooth and continuous.

5. The semiconductor structure of claim 3, wherein the conductive filling material is TiN, W, Ru, TaN, or Cu, and wherein the conductive liner comprises a seed material that is TiN or TaN and is different from the filling conductive material.

6. The semiconductor structure of claim 1, wherein a top layout of the vertical conductive portion is substantially round-shaped or slit-shaped from a top view.

7. The semiconductor structure of claim 6, wherein a width of the vertical conductive portion at a level of the first lateral conductive portion is greater than a width of the first lateral conductive portion in a second lateral direction perpendicular to the first lateral direction.

8. The semiconductor structure of claim 1, wherein the interconnect structure is disposed on a frontside of a semiconductor substrate of a semiconductor die, and wherein a semiconductor device is arranged on the frontside of the semiconductor substrate between the semiconductor substrate and the interconnect structure.

9. The semiconductor structure of claim 1, further comprising:
a plurality of IC chips embedded in a molding compound, wherein the interconnect structure overlies and is electrically coupled to the plurality of IC chips.

10. The semiconductor structure of claim 1, wherein the interconnect structure is disposed on a backside of a semiconductor substrate of a semiconductor die, and wherein a semiconductor device is on a frontside of the semiconductor substrate opposite the backside.

11. A method of manufacturing an integrated chip structure, comprising:
forming a first dielectric layer over a semiconductor substrate;
forming a first sacrificial layer in an upper portion of the first dielectric layer;
forming a deep opening vertically through the first sacrificial layer, and the first dielectric layer;
performing a removal process to laterally widen the deep opening, and remove the first sacrificial layer laterally exposed by the deep opening to form a first lateral opening; and
filling the deep opening and the first lateral opening with a conductive filling material to respectively form a deep conductive via and a first conductive layer, wherein the deep conductive via and the first conductive layer form an interconnect structure.

12. The method of claim 11, further comprising:
prior to filling the deep opening, depositing a conductive liner layer on inner surfaces of the deep opening and the first lateral opening.

13. The method of claim 11, wherein performing the removal process comprises performing a lateral wet etching.

14. The method of claim 11, further comprising:
forming a second dielectric layer over the first dielectric layer and the first conductive layer; and
forming a second conductive layer in an upper portion of the second dielectric layer and in contact with the deep conductive via.

15. The method of claim 11, wherein forming the first sacrificial layer comprises:
forming a first recess in the upper portion of the first dielectric layer;
filling a sacrificial material in the first recess; and
removing the sacrificial material outside the first recess.

16. The method of claim 14, wherein forming the second sacrificial layer comprises:
forming a second recess in the upper portion of the second dielectric layer;
filling a sacrificial material in the second recess; and
removing the sacrificial material outside the second recess.

17. A method of manufacturing an integrated chip structure, comprising:
forming a first etch stop layer over a semiconductor substrate;
forming a lower portion of a first dielectric layer over the first etch stop layer;
forming a first sacrificial layer in the first dielectric layer, through the lower portion of the first dielectric layer and through the first etch stop layer;
forming a second etch stop layer over the first dielectric layer;
forming a lower portion of a second dielectric layer over the second etch stop layer;
forming a second sacrificial layer in the second dielectric layer, through the lower portion of the second dielectric layer and through the second etch stop layer;
forming a deep opening through an upper portion of the second dielectric layer, the second sacrificial layer, an upper portion of the first dielectric layer, and the first sacrificial layer;
performing a removal process to laterally remove the first sacrificial layer and the second sacrificial layer that are laterally exposed by the deep opening to respectively form a first lateral opening and a second lateral opening and to laterally widen the deep opening; and
filling the deep opening, the first lateral opening, and the second lateral opening with a conductive filling material to respectively form a deep conductive via, a first conductive layer, and a second conductive layer.

18. The method of claim 17, wherein forming the first sacrificial layer in the first dielectric layer comprises:
forming the lower portion of the first dielectric layer over the first etch stop layer;
forming a first recess through the lower portion of the first dielectric layer and the first etch stop layer;
filling a sacrificial material in the first recess;
removing the sacrificial material outside the first recess; and
forming the upper portion of the first dielectric layer overlaying the first sacrificial layer and the lower portion of the first dielectric layer.

19. The method of claim 18, wherein forming the first recess comprises:
forming a first portion of the first recess through the lower portion of the first dielectric layer by a first etching process that stops on the first etch stop layer; and
forming a second portion of the first recess through the first etch stop layer by a second etching process.

20. The method of claim 17, wherein the deep conductive via, the first conductive layer, and the second conductive layer form an interconnect structure, and wherein the deep conductive via is formed to protrude from a lower surface of the first conductive layer and from an upper surface of the second conductive layer.
